(19) United States
(12) Patent Application Publication
(10) Pub. No.: US 2025/0293144 A1
(43) Pub. Date: Sep. 18, 2025

(54) ARCHITECTURE AND METHOD OF MAKING A SYSTEM LEVEL SEMICONDUCTOR IC-SUBSTRATE, INTERCONNECT FABRIC AND INTEGRATED ELECTRONIC SYSTEMS

(71) Applicant: S Squared IP, LLC, Wilmington, DE (US)

(72) Inventor: Islam Salama, Queens Creek, AZ (US)

(21) Appl. No.: 19/221,413

(22) Filed: May 28, 2025

Related U.S. Application Data
(63) Continuation-in-part of application No. 18/121,746, filed on Mar. 15, 2023.
(60) Provisional application No. 63/320,560, filed on Mar. 16, 2022.
(60) Provisional application No. 63/652,241, filed on May 28, 2024.

(51) Int. Cl. H01L 23/498; H01L 21/48; H01L 23/14

(52) U.S. Cl. CPC H01L 23/49877; H01L 21/4846; H01L 23/147; H01L 23/49894

(57) ABSTRACT

An improved semiconductor IC substrate and method of making is disclosed for supporting and interconnecting integrated circuit die or multiple dies comprises a silicon carbide (SiC) interposer having a first outer surface and a second outer surface. A plurality of interposer connectors are formed in situ within the silicon carbide (SiC) interposer. A dielectric layer has a first outer surface and a second outer surface. A plurality of electrical connectors are formed within the dielectric layer. An interface is between the second outer surface of the silicon carbide (SiC) interposer and the first outer surface of the dielectric layer for electrically connecting the plurality of interposer connectors to the plurality of electrical connectors.

### CROSS-REFERENCE TO RELATED APPLICATIONS

This is a continuation-in-part of U.S. patent application Ser. No. 18/121,746 filed Mar. 15, 2023. All subject matter set forth in application Ser. No. 18/121,746 is hereby incorporated by reference into the present application as if fully set forth herein.

U.S. patent application Ser. No. 18/121,746 filed Mar. 15, 2023 claims benefit of U.S. Patent Provisional application No. 63/320,560 filed Mar. 16, 2022. All subject matter set forth in provisional application No. 63/320,560 is hereby incorporated by reference into the present application as if fully set forth herein.

This application claims the benefit of U.S. Patent Provisional Application No. 63/652,241 filed May 28, 2024. All subject matter set forth in Provisional Application No. 63/652,241 is hereby incorporated by reference into the present application as if fully set forth herein.

### FIELD OF THE INVENTION

This invention relates to integrated circuits and more particularly to an improved interposer and package and method of making with improved density, conductivity, signal transfer speed, power and heat dissipation.

### BACKGROUND OF THE INVENTION

The continued increase in the density of electrical components in integrated circuit has promoted the use of silicon interposers for interconnection of the integrated circuits to a substrate and a circuit board. The use of silicon interposers enables the integrated circuits (dies) to be closely mounted on top of the silicon interposer with the integrated circuits being interconnected by through vertical conductors called through silicon vias (TSV) and horizontal conductors called redistribution layers (RDL). Silicon interposers have also included active components to provide electrical communication between the integrated circuits and the substrate.

In my research for my doctoral thesis, I had the honor of working with Aravinda Kar Ph.D. and Nathaniel R. Quick Ph.D. in investigating the properties and possible applications of laser processed silicon carbide (SiC). The research with Dr. Kar and Dr. Quick resulted in my published doctorial thesis entitled LASER DOPING AND METALLIZATION OF WIDE BANDGAP MATERIALS: SiC, GaN and AlN though the Center for Research and Education in Optics and Lasers (CREOL) at the University of Central Florida Spring Term 2003.

In addition, a technical paper entitled Microstructural and electrical resistance analysis of laser-processed SiC substrates for wide bandgap semiconductor materials was published in the JOURNAL OF MATERIALS SCIENCE 40 (2005) 3969-3980I. A. by IL Salama, N. R. Quick and A. Kar.

Finally, U.S. Pat. No. 7,268,063 was issued based on the above research. U.S. Pat. No. 7,268,063 to Kar, Quick and Salama discloses a process for in-situ fabricating a semiconductor in a substrate. A substrate is ablated with a first laser beam to form a void therein. A first conductive element is formed in the void of the substrate with a second laser beam. A semiconductor material is deposited upon the first conductive element with a third laser beam operating in the presence of a depositing atmosphere. A second conductive element is formed on the first semiconductor material with a fourth laser beam. The process may be used for fabricating a Schottky barrier diode or a junction field transistor and the like.

Dr. Kar and Dr. Quick continued the research into silicon carbide and various other wide bandgap semiconductors. The following United States patents represent the continued research of Dr. Kar and Dr. Quick as well as other collaborators.

U.S. Pat. No. 5,145,741 to Quick discloses room temperature electrically conductive or semiconductive ceramic paths or areas produced on carbide and nitride ceramic substrates by a process of controlled oxidation using localized thermal heating (e.g., laser heating) by tracing desired paths onto the substrates, where air is the source of oxygen. In another embodiment, nitride and carbide ceramic substrates are converted to electroconductive or semiconductive ceramics where the substrate is characterized as whiskers, fibers, flakes or platelets whose dimensions are in the micron range, by controlled oxidation as prescribed by laser beam processing. The resulting conductive or semiconductive paths or surfaces of the substrate comprise electrically conductive or semiconductive non-stoichiometric aluminum-nitrogen-oxygen ceramic, when the initial ceramic substrate material is aluminum nitride (AlN); and electrically conductive or semiconductive non-stoichiometric silicon-carbon-oxygen ceramic, when the initial ceramic material used is silicon carbide (SiC). The path cut into the surface on a flat substrate can serve e.g. as electrical interconnects akin to printed circuitry on a wiring board and patterns of semiconductors formed can serve e.g. as semiconductive devices akin to rectifier devices. In the instance of the whiskers, fibers, flakes or platelets, the electrically conductive surfaces thereof may be used directly or enhanced for example, by coating other conductor metal or alloys onto the surface for uses e.g. as composite materials in matrices at the microstructural level.

U.S. Pat. No. 5,837,607 to Quick discloses laser apparatus and methods for synthesizing areas of ceramic substrates or thin films, such ceramics as Silicon Carbide and Aluminum Nitride, to produce electronic devices and circuits as integral electronic circuit components thereof. Circuit components such as conductive tabs, interconnects, wiring patterns, resistors, capacitors, insulating layers and semiconductors are synthesized on the surfaces and within the body of such ceramics. Selected groupings and arrangements of these electronic circuit components within the substrates or thin films provide a wide range of circuits for applications such as digital logic elements and circuits, transistors, sensors for measurements and monitoring effects of chemical and/or physical reactions and interactions of materials, gases, devices or circuits that may utilize sensors. The electronic elements and components offer the advantages of providing thermal compatibilities with the substrate, since they are an integral part thereof and consequently are compatible therewith regarding thermal coefficients of expansion and thermal dissipation.

U.S. Pat. No. 6,025,609 to Quick discloses laser apparatus and methods for synthesizing areas of ceramic substrates or thin films, such ceramics as Silicon Carbide and Aluminum Nitride, to produce electronic devices and circuits as integral electron circuit components thereof. Circuit components such as conductive tabs, interconnects, wiring patterns, resistors, capacitors, insulating layers and semiconductors are synthesized on the surfaces and within the body of such ceramics. Selected groupings and arrangements of these electronic circuit components within the substrates or thin films provide a wide range of circuits for applications such as digital logic elements and circuits, transistors, sensors for measurements and monitoring effects of chemical and/or physical reactions and interactions of materials, gases, devices or circuits that may utilize sensors. The electronic elements and components offer the advantages of providing thermal compatibilities with the substrate, since they are an integral part thereof and consequently are compatible therewith regarding thermal coefficients of expansion and thermal dissipation.

U.S. Pat. No. 6,054,375 to Quick discloses laser apparatus and methods for synthesizing areas of ceramic substrates or thin films, such ceramics as Silicon Carbide and Aluminum Nitride, to produce electronic devices and circuits as integral electron circuit components thereof. Circuit components such as conductive tabs, interconnects, wiring patterns, resistors, capacitors, insulating layers and semiconductors are synthesized on the surfaces and within the body of such ceramics. Selected groupings and arrangements of these electronic circuit components within the substrates or thin films provide a wide range of circuits for applications such as digital logic elements and circuits, transistors, sensors for measurements and monitoring effects of chemical and/or physical reactions and interactions of materials, gases, devices or circuits that may utilize sensors. The electronic elements and components offer the advantages of providing thermal compatibilities with the substrate, since they are an integral part thereof and consequently are compatible therewith regarding thermal coefficients of expansion and thermal dissipation.

U.S. Pat. No. 6,271,576 to Quick discloses laser apparatus and methods for synthesizing areas of ceramic substrates or thin films, such ceramics as Silicon Carbide and Aluminum Nitride, to produce electronic devices and circuits such as sensors as integral electro circuit components thereof. Circuit components such as conductive tabs, interconnects, wiring patterns, resistors, capacitors, insulating layers and semiconductors are synthesized on the surfaces and within the body of such ceramics. Selected groupings and arrangements of these electronic circuit components within the substrates or thin films provide a wide range of circuits for applications such as digital logic elements and circuits, transistors, sensors for measurements and monitoring effects of chemical and/or physical reactions and interactions of materials, gases, devices or circuits that may utilize sensors. The electronic elements and components offer the advantages of providing thermal compatibilities with the substrate, since they are an integral part thereof and consequently are compatible therewith regarding thermal coefficients of expansion and thermal dissipation.

U.S. Pat. No. 6,670,693 to Quick discloses a laser apparatus and methods are disclosed for synthesizing areas of wide-bandgap semi-conductor substrates or thin films, including wide-bandgap semiconductors such as silicon carbide, aluminum nitride, gallium nitride and diamond to produce electronic devices and circuits such as integral electronic circuit and components thereof.

U.S. Pat. No. 6,930,009 to Quick discloses a laser apparatus and methods are disclosed for synthesizing areas of wide-bandgap semiconductor substrates or thin films, including wide-bandgap semiconductors such as silicon carbide, aluminum nitride, gallium nitride and diamond to produce electronic devices and circuits such as integral electronic circuit and components thereof.

U.S. Pat. No. 6,939,748 to Quick discloses a method is disclosed for making a nano-size semiconductor component within a wide-bandgap semiconductor substrate. A first thermal energy beam is directed onto a first portion of the wide-bandgap semiconductor substrate to change the structure of the wide-bandgap semiconductor substrate into a first element of the semiconductor comprising the steps of directing a thermal energy component. A second thermal energy beam is directed onto a second portion of the wide-bandgap semiconductor substrate adjacent to the first portion to form a second element of the semiconductor component.

U.S. Pat. No. 7,419,887 to Quick and Kar discloses an apparatus and method is disclosed for forming a nanostructure on a substrate with nano particles. The nano particles are deposited through a nano size pore onto the substrate. A laser beam is directed through a concentrator to focus a nano size laser beam onto the deposited nano particles on the substrate. The apparatus and method is suitable for fabricating patterned conductors, semiconductors and insulators on semiconductor wafers of a nano scale line width by direct nano scale deposition of materials.

U.S. Pat. No. 7,811,914 to Quick and Kar disclose an apparatus and method is disclosed for increasing the thermal conductivity in a substrate of a non-wide bandgap material beam onto the substrate in the presence of a first doping gas for converting a region of the substrate into a wide bandgap material to enhance the thermal conductivity of the substrate for cooling the non-wide bandgap material. In one example, the invention is incorporated into a carbon rich layer formed within the wide bandgap material. In another example, the invention is incorporated into a carbon rich layer formed within the wide bandgap material having basal planes disposed to extend generally outwardly relative to an external surface of the substrate to enhance the cooling of the substrate.

U.S. Pat. No. 7,897,492 to Quick discloses a method is disclosed for forming a layer of a wide bandgap material in a non-wide bandgap material. The method comprises providing a substrate of a non-wide bandgap material and converting a layer of the non-wide bandgap material into a layer of a wide bandgap material. An improved component such as wide bandgap semiconductor device may be formed within the wide bandgap material through a further conversion process.

The present invention is an improvement to prior inventions related to an semiconductor IC-substrate and integrated electronic systems.

Therefore, it is an objective of this invention to improve the prior art set forth above by providing an improved architecture and method of making a system level semiconductor IC-substrate, interconnect fabric and integrated electronic systems which is a major advancement in the solid state art.

Another objective of this invention is to provide an improved semiconductor IC-substrate which provides superior interconnect density, conductivity and heat dissipation for integrated circuits.

The foregoing has outlined some of the more pertinent objects of the present invention. These objects should be construed as being merely illustrative of some of the more prominent features and applications of the invention. Many other beneficial results can be obtained by modifying the invention within the scope of the invention. Accordingly other objects in a full understanding of the invention may be had by referring to the summary of the invention, the detailed description describing the preferred embodiment in addition to the scope of the invention defined by the claims taken in conjunction with the accompanying drawings.

### SUMMARY OF THE INVENTION

The present invention is defined by the appended claims with specific embodiments being shown in the attached drawings. For the purpose of summarizing the invention, the invention relates to an improved semiconductor IC substrate is disclosed for supporting and interconnecting integrated circuit die or multiple dies comprises a silicon carbide (SiC) interposer having a first outer surface and a second outer surface. A plurality of interposer connectors are formed in situ within the silicon carbide (SiC) interposer. A dielectric layer has a first outer surface and a second outer surface. A plurality of electrical connectors are formed within the dielectric layer. An interface is between the second outer surface of the silicon carbide (SiC) interposer and the first outer surface of the dielectric layer for electrically connecting the plurality of interposer connectors to the plurality of electrical connectors.

In alternative embodiment of the invention, the second outer surface of the silicon carbide (SiC) interposer abuts the first outer surface of the dielectric layer. A second dielectric layer has a first outer surface and a second outer surface. A second plurality of electrical connectors are formed within the second dielectric layer. A second interface is between the first outer surface of the silicon carbide (SiC) interposer and the second outer surface of the second dielectric layer for electrically connecting the plurality of interposer connectors to the second plurality of electrical connectors. The silicon carbide (SiC) interposer is interposed between the dielectric layer and the second dielectric layer defining a silicon carbide (SiC) interposer core.

In another embodiment of the invention, the second outer surface of the silicon carbide (SiC) interposer abuts the first outer surface of the dielectric layer. A second silicon carbide (SiC) interposer has a first outer surface and a second outer surface. A second plurality of interposer connectors is formed in situ within the second silicon carbide (SiC) interposer. A second interface is between the first outer surface of the second silicon carbide (SiC) interposer and the second outer surface of the dielectric layer for electrically connecting the second plurality of interposer connectors to the plurality of electrical connectors. The dielectric layer is interposed between the silicon carbide (SiC) interposer and the second silicon carbide (SiC) interposer defining a dielectric layer core.

In another embodiment of the invention, a first integrated circuit die is electrically coupled to the first outer surface of the silicon carbide (SiC) interposer. An second integrated circuit die is electrically coupled to the second outer surface of the second silicon carbide (SiC) interposer. The first integrated circuit die abuts the first silicon carbide (SiC) interposer and the second integrated circuit die abuts the second silicon carbide (SiC) interposer defining a double-sided assembly of chiplets.

In another embodiment of the invention the dielectric layer defines a hybrid dielectric layer.

The invention also incorporates a method for creating an improved semiconductor IC substrate for supporting and interconnecting integrated circuit die or multiple dies, the method comprising the steps of depositing a silicon carbide (SiC) layer on a dielectric layer. A laser irradiates the silicon carbide (SiC) to form carbon electrical connectors. An interconnection is created in the dielectric layer by semi additive and/or, damascene and/or dual damascene pattering to create a fan out and chip to chip interconnection.

The foregoing has outlined rather broadly the more pertinent and important features of the present invention in order that the detailed description that follows may be better understood so that the present contribution to the art can be more fully appreciated. Additional features of the invention will be described hereinafter which form the subject of the claims of the invention. It should be appreciated by those skilled in the art that the conception and the specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a laser beam from a laser contacting a silicon carbide (SiC) substrate;

FIG. 2 is a view similar to FIG. 1 illustrating a laser beam from a laser contacting a silicon carbide (SiC) substrate;

FIG. 3 is a cross-sectional view of FIG. 2;

FIG. 3A is a cross-sectional view of the state-of-the-art interconnected;

FIG. 3B is a top view of layer 2 in FIG. 3A;

FIG. 3C is a cross-sectional view of the present invention illustrating laser conversion interconnection;

FIG. 3D is a top view of FIG. 3C;

FIG. 3E illustrates different geometric shapes which the laser beam may create;

FIG. 3F illustrates a first and second laser beam with circular cross-sections;

FIG. 3G illustrates shutter elements placed within the beam optical path;

FIG. 3H illustrates a top hat laser beam with uniform intensity profile;

FIG. 3I illustrates a similar structure which may be created in silicon carbide (SiC) by direct-write a Gaussian laser beam using Galvanometer-optical elements;

FIG. 3J illustrates the resultant carbon rich conductive serpentine structure created with the laser in FIG. 3I;

FIG. 3K is an isometric view of FIG. 3 illustrating in-situ laser converted 3D monolithic vias;

FIG. 3L is a schematic of one large contact split into 3 different monolithic vias;

FIG. 4 illustrates the laser conversion processing used throughout the full thickness;

FIG. 4A illustrates the state of the art semi addictive interconnect fabrication process;

FIG. 4A1 illustrates a second state of the art semi addictive interconnect fabrication process;

FIG. 4A2 illustrates state of the art semi additive interconnect fabrication processes, a dual damascene patterning process;

FIG. 4B illustrates examples of the 3DR structures created laser thickness without drilling;

FIG. 4C illustrates a layer of silicon carbide (SiC) structure where in the laser quantum conversion patterning creates direct 3D structure throughout the thickness at variable angles;

FIG. 5 illustrates a silicon carbide (SiC) substrate prepared with machine grooves housing multiple chips/chiplets with different functionality;

FIG. 5A illustrates a first state of the art 2.5D interconnect structures, 2.5D Bridge architecture landscape;

FIG. 5A1 illustrates a second state of the art 2.5D interconnect structures, 2.5D Bridge architecture landscape;

FIG. 5A2 illustrates a state of the art 2.5D interconnect structures, 2.5D Bridge architecture landscape, TSMC silicon interposer;

FIG. 5B illustrates how the silicon carbide (SiC) interposer may be customized depending on the specification of each chip;

FIG. 6 illustrates a 3-D integration on laser inverted silicon carbide (SiC) interposer and silicon carbide (SiC) Thermo chip;

FIG. 6A illustrates an architecture option including a laser converted silicon carbide (SiC) interposer, a laser converted silicon carbide (SiC) Thermo chips and a substrate;

FIG. 6B illustrates an alternative architecture option illustrating a compact structure using machined silicon carbide (SiC) interposer for eliminating the need of silicon carbide (SiC) Thermo chips;

FIG. 6C illustrates a first simultaneous fabrication of QCIA (Quantum Conversion Integration Architecture) architecture enabling accelerated run rate an improved yield;

FIG. 6C1 illustrates a second simultaneous fabrication of QCIA (Quantum Conversion Integration Architecture) architecture enabling accelerated run rate an improved yield;

FIG. 6C2 illustrates the completed fabrication of QCIA (Quantum Conversion Integration Architecture) architecture enabling accelerated run rate an improved yield;

FIG. 6D illustrates a customized point to point connection using QCIA (Quantum Conversion Integration Architecture) architecture and laser conversion patterning or quantum conversion patterning (QCP);

FIG. 6E is an isometric view of FIG. 6 illustrating 3D integration of multiple integrated circuits chips connected at different faces of the silicon carbide (SiC) interposer;

FIG. 6F1 is a first illustration of the current state of practice in the industry for attempting to offer die stacking;

FIG. 6F2 is a second illustration of the current state of practice in the industry for attempting to offer die stacking;

FIG. 6F3 is a third illustration of the current state of practice in the industry for attempting to offer die stacking;

FIG. 6F4 is a fourth illustration of the current state of practice in the industry for attempting to offer die stacking;

FIG. 7 illustrates the option for in-situ deposition and patterning of QCIA on organic substrates;

FIG. 8 illustrates an architecture option for the improved interposer showing multiple different redistribution layers on both sides of the interposer outer surfaces;

FIG. 9 illustrates an architecture option for the improved packaging device in which the improved interposer shown in FIG. 8 is further assembled a top of a high density interconnect substrate;

FIG. 9A is an enlarged portion of FIG. 9;

FIG. 9B is an enlarged portion of FIG. 9A;

FIG. 10 illustrates a first parallel processing nature of assembling the different layers illustrated in FIG. 9;

FIG. 10A illustrates a second parallel processing nature of assembling the different layers illustrated in FIG. 9;

FIG. 11 illustrates the method of making the improved interposer with multiple redistribution layers using two different variations of the process of fabrication;

FIG. 12 is a schematic representation of a single unit of the QCIA interconnect structure;

FIG. 13 is an illustration schematic of a substrate core structure made possible using the proposed quantum conversion patterning process and materials set;

FIG. 14 is a view of a current prior art interposer;

FIG. 15 is a side view of an improved interposer having carbon electrical connectors which have omni directional geometry and variable depth interconnections.

FIG. 16 is a side view of a single sided quantum conversion integration architecture (QCIA) including the interposer interfacing with a plurality of chiplets and a substrate;

FIG. 17 is a side view of a double sided quantum conversion integration architecture (QCIA) including the interposer interfacing with an upper and lower substrate;

FIG. 18 is a side view of a system level panel substrate (SLPS) utilizing quantum conversion integration architecture (QCIA) including a plurality of interposers interfacing with a plurality of chiplets and a plurality of substrates;

FIG. 19 is a side view of a single sided quantum conversion integration architecture (QCIA) including the interposer interfacing with a glass substrate;

FIG. 20 is a side view of a single sided quantum conversion integration architecture (QCIA) including the interposer interfacing with a glass substrate wherein the glass substrate include a through glass vias and optical waveguide structure;

FIG. 21 is a side view of a single sided quantum conversion integration architecture (QCIA) including a plurality of interposers positioned within recesses located in the substrate;

FIG. 22 is a side view of a single sided quantum conversion integration architecture (QCIA) including the interposer interfacing with a silicon substrate;

FIG. 23 is a side view of a double sided quantum conversion integration architecture (QCIA) including an upper interposer and a lower interposer for defining a substrate core having a plated through hole;

FIG. 24 is a side view of a double sided quantum conversion integration architecture (QCIA) including an upper interposer and a lower interposer for defining a substrate core having a plated through hole and components;

FIG. 25 is a side view of a single sided quantum conversion integration architecture (QCIA) including the interposer interfacing with a glass substrate and the glass substrate interfacing with a polymeric substrate;

FIG. 26 is a side view of a single sided quantum conversion integration architecture (QCIA) including the interposer interfacing with a silicon substrate and the silicon substrate interfacing with a polymeric substrate;

FIG. 27 is a side view of a single sided quantum conversion integration architecture (QCIA) including the interposer positioned between an upper substrate and a lower substrate for defining an interposer core;

FIG. 28 is a side view of a single sided quantum conversion integration architecture (QCIA) including the interposed positioned between an upper substrate and a first lower substrate and a second lower substrate for defining an interposer core;

FIG. 29 is a flow diagram illustrating the method of making quantum conversion integration architecture (QCIA);

FIG. 30 illustrates the method of making the improved quantum conversion integration architecture (QCIA) with multiple redistribution layers using a first process of fabrication;

FIG. 31 illustrates the method of making the improved quantum conversion integration architecture (QCIA) with multiple redistribution layers using a second process of fabrication:

FIG. 32 is a side view of a double sided quantum conversion integration architecture (QCIA) including the interposed positioned between an upper substrate and a lower substrate for defining an interposer core;

FIG. 33 is an alternative side view of a double sided quantum conversion integration architecture (QCIA) including the interposed positioned between an upper substrate and a lower substrate for defining an interposer core;

FIG. 34 illustrates the method of making quantum conversion patterning (QCP) available with quantum conversion integration architecture (QCIA);

FIG. 35 illustrates the method of making vias available with quantum conversion integration architecture (QCIA);

FIG. 36 is a side view of a single sided quantum conversion integration architecture (QCIA) utilized with multiple substrate layers including integrated electronic and/or optoelectronic system;

FIG. 36A is an enlarged portion of FIG. 36;

FIG. 36B is an enlarged portion of FIG. 36;

FIG. 37 is a table illustrating design rules capabilities and scalability for the quantum conversion integration architecture (QCIA) shown in FIGS. 19 and 20;

FIG. 38 is a table illustrating the manufacturing scale of the quantum conversion integration architecture (QCIA);

FIG. 39 is a flow diagram illustrating the method of making quantum conversion integration architecture (QCIA) shown in FIGS. 36, 36A and 36B; and

FIG. 39A is a continuation flow diagram from FIG. 39.

To facilitate understanding, identical reference numerals have been used, where possible, to designate identical elements that are common to the figures. It is contemplated that elements and features of one embodiment may be beneficially incorporated in other embodiments without further recitation.

### DETAILED DISCUSSION

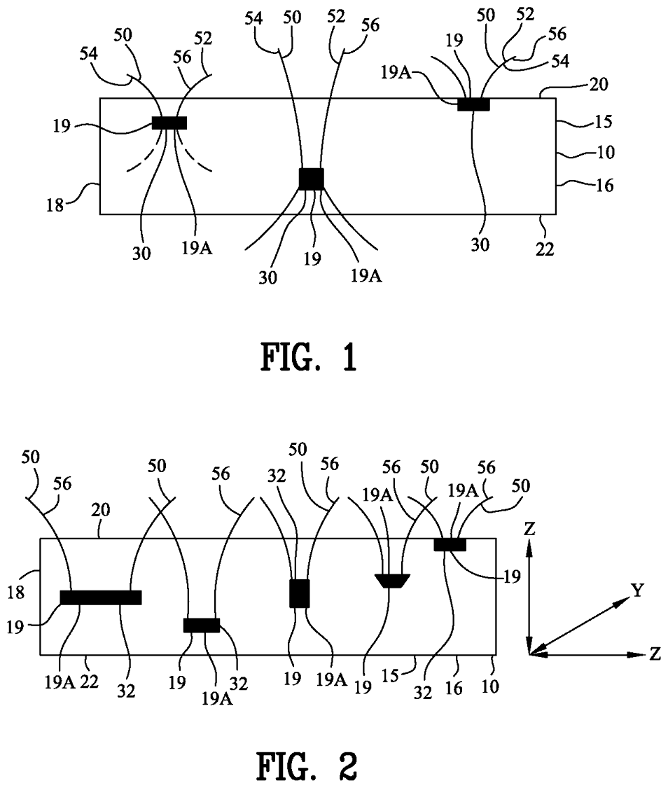

FIGS. 1-4, 4B-5, 5B-6E and 7 illustrate an improved interposer 10 for connecting an integrated circuit die 12 or multiple dies 12 to a substrate 14. The interposer 10 may comprises a silicon carbide (SiC) interposer 16. The interposer 10 has a first outer surface 20 and a second outer surface 22 and a plurality of connectors 30 formed in situ within the silicon carbide (SiC) interposer 16 for connecting the integrated circuit dies 12 to the substrate 14.

The plurality of connectors 30 may include carbon electrical connectors 32. The plurality of connectors 32 may include optical wave guide connectors 34. Each of the optical wave guide connectors 34 may comprises a tunnel 36 formed in the silicon carbide (SiC) 16 by carbon rich tunnel walls 38.

The plurality of connectors 30 formed in situ within the silicon carbide (SiC) interposer 16 may be formed at an angle 40 relative to the first outer surface 20. The plurality of connectors 30 formed in situ within the silicon carbide (SiC) interposer 16 may be an angular monolithic 42 via formed at an angle 40 relative to the first outer surface 20. The plurality of connectors 30 may include carbon electrical connectors 32 formed by laser irradiation 50 of the silicon carbide (SiC) 16 to form the carbon electrical connectors 32.

The plurality of connectors 30 may include optical wave guide connectors 34 formed by laser irradiation 50 of the silicon carbide (SiC) 16 to form the optical wave guide 34.

The subject invention may further include a recess 60 formed in the first outer surface 20 and the integrated circuit die 12 is disposed in the recess 60 and thermally coupled to the silicon carbide (SiC) interposer 16 for providing a heat sink 62 for the integrated circuit die 12. A recess 60 may be formed in the first outer surface 20 by a laser ablating process 52 and the integrated circuit die 12 is disposed in the recess 60 and thermally coupled to the silicon carbide (SiC) interposer 16 for providing a heat sink 62 for the integrated circuit die 12.

The subject invention includes an improved interposer 10 for connecting an integrated circuit dies 12 to a substrate 14 comprising a wide bandgap interposer 18 having a first outer surface 20 and a second outer surface 22. A plurality of connectors 30 are formed in situ within wide bandgap interposer 18 for connecting the integrated circuit die 12 to the substrate 14. The circuit dies 12 may include Si, SiGe, GaN, SiC, the combination of two or more of Si, SiGe, GaN, SiC or other dies.

The subject invention includes an improved interposer 10 for connecting integrated circuit dies 12 to a substrate 14 comprises a wide bandgap interposer 18 having a first outer surface 20 and a second outer surface 22 and multiple redistribution layers 70 on top of the first outer surface 20 and below the second outer surface 22. A plurality of connectors 30 are formed in situ within wide bandgap interposer 18 for connecting the silicon integrated circuit die 12 to the substrate 14. A plurality of connectors 30 are formed within the redistribution layers 70 for connecting the silicon integrated circuit die 12 to the substrate 14 and for interconnecting the redistribution layers 70 among each other's across both the first outer surface 20 and the second outer surface 22 of the interposer 10.

The subject invention includes an improved interposer 10 for connecting integrated circuit dies 12 to a substrate 14 comprising a wide bandgap interposer 18 having a first outer surface 20 and a second outer surface 22 and multiple redistribution layers 70 on top of the first outer surface 20 and below the second outer surface 22. The number, material type and dimensions of the redistribution layers 70 on both outer surfaces 20 and 22 of the interposer 10 need not to be the same. A plurality of connectors 30 are formed in situ within wide bandgap interposer 18 for connecting the silicon integrated circuit die 12 to the substrate 14. A plurality of connectors 30 are formed within the redistribution layers 70 for connecting the silicon integrated circuit die 12 to the substrate 14 and for interconnecting the redistribution layers 70 among each other's across both outer surfaces 20 and 22 of the interposer 10. The plurality of connectors 30 may take different dimensions and be constructed at multiple different angels 40.

The wide bandgap interposer 18 is selected from the group consisting of silicon carbide (SiC), gallium nitride (GaN) aluminum nitride (AlN), synthetic diamond, glass and their respective compounds and alloyed or hybrid variants engineered to enhance the quantum conversion process discussed in this invention.

The wide bandgap interposer 18 may include a combination of compounds selected from the group consisting of silicon carbide (SiC), gallium nitride (GaN) aluminum nitride (AlN), synthetic diamond, glass and their respective compounds and alloyed variants engineered to enhance the quantum conversion process discussed in this invention.

The plurality of connectors 30 may include carbon electrical connectors 32 formed in the wide bandgap material 18 to form the carbon electrical connectors 32. The plurality of connectors 30 may include optical wave guide connectors 34 formed in the wide bandgap material 18 to form the optical wave guide 34. The plurality of connectors 30 are optical wave guide connectors 34 and each of the optical wave guide connectors 34 comprise a tunnel 36 formed in the wide bandgap material 18 by carbon rich tunnel walls 38.

A recess 60 may be formed in the first outer surface 20. The integrated circuit die 12 is disposed in the recess 60 and is thermally coupled to the wide bandgap material 18 for providing a heat sink 62 for the integrated circuit die 12.

A recess 60 may be formed in the first outer surface 20 by a laser ablating process 52 and the integrated circuit die 12 is disposed in the recess 60 and is thermally coupled to the wide bandgap material 18 for providing a heat sink 62 for the integrated circuit die 12.

The subject invention further includes an improved packaging device 100 for connecting integrated circuit die 12 to a circuit board 110 comprising a silicon carbide (SiC) material 16 having a first outer surface 20 and a second outer surface 22. A recess 60 is formed in the first outer surface 20. The integrated circuit die 12 is disposed in the recess 60 and is thermally coupled to the silicon carbide (SiC) material 16 for providing a heat sink 62 for the integrated circuit die 12. A plurality of connectors 30 are formed in situ within the silicon carbide (SiC) material 16 for connecting the integrated circuit die 12 to the second outer surface 22. The second outer surface 22 of the silicon carbide (SiC) interposer 16 is directly connected to the circuit board 110.

The subject invention further includes an improved packaging device 100 for connecting integrated circuit dies 12 comprises a silicon carbide (SiC) material 16 having a first outer surface 20 and a second outer surface 22. A recess 60 is formed in the first outer surface 20. A first integrated circuit die 112 is disposed in the recess 60 and is thermally coupled to the silicon carbide (SiC) material 16 for providing a heat sink 62 for the integrated circuit die 12. A second recess 64 is formed in the second outer surface 22. A second integrated circuit die 114 is disposed in the second recess 64 and is thermally coupled to the silicon carbide (SiC) material 16 for providing a heat sink 62 for the second integrated circuit die 114. A plurality of connectors 30 are formed in situ within the silicon carbide (SiC) material 16 for connecting the first integrated circuit die 112 and the second integrated circuit die 114 to a third outer surface 24 of the silicon carbide (SiC) interposer 16.

The subject invention further includes an improved interposer system 120 comprises a first silicon carbide (SiC) interposer 122 having a first outer surface 124 and a second outer surface 126 with a first recess 60 and a second recess 64 defined in the first outer surface 124 and second outer surface 126. A first integrated circuit die 112 and a second integrated circuit die 114 are disposed in the first recess 60 and second recess 64 and are thermally coupled to the first silicon carbide (SiC) interposer 112 for providing a heat sink 62 for the first integrated circuit die 112 and second integrated circuit die 114. A second silicon carbide (SiC) interposer 132 has third outer surface 134 and a fourth outer surface 136 with a third recess 66 and a fourth recess 68 defined in the third outer surface 134 and a fourth outer surfaces 136. A third integrated circuit die 116 and a fourth integrated circuit die 118 are disposed in the third recess 66 and a fourth recess 68 and are thermally coupled to the second silicon carbide (SiC) interposer 132 for providing a heat sink 62 for the integrated circuit die 116 and 118. The first silicon carbide (SiC) interposer 122 is stacked upon or adjacent to the second silicon carbide (SiC) interposer 132 for interconnecting the first integrated circuit dies 112, 114, 116 and 118.

The subject invention further includes an improved packaging substrate core 160 for constructing high density interconnect substrate 162 with multiple build up layers 164 on both surfaces of the core 160. The core 160 comprises a silicon carbide (SiC) material 16 having a first outer surface 20 and a second outer surface 22. The SiC material 16 has plated through holes 170 and plurality of connectors 172 formed within the core material structure 160 using both laser irradiation conversion 50 and/or laser drilling 54.

FIG. 1 illustrates a laser beam 56 from a laser contacting a silicon carbide (SiC) substrate 14 wherein the laser converts the silicon carbide (SiC) 15 for creating conductive materials 19 in otherwise insulating or semi-conductive silicon carbide (SiC) 15. FIG. 1 further illustrates a cross-section of laser conversion creating quantum-pretictic materials 19A that are conductive thermally and electrically. The position, size, configuration of the conductive structure 19 is manipulated by the laser beam 56 profile, laser processing parameters and the processing ambient.

FIG. 2 is a cross-section view similar to FIG. 1 illustrating the shape, location, size and thickness of laser converted structures 19 may be controlled by manipulating the laser beam 56 profile, laser radiation conditions and relative motion between the beam 56, the substrate 14 and the work surface 20.

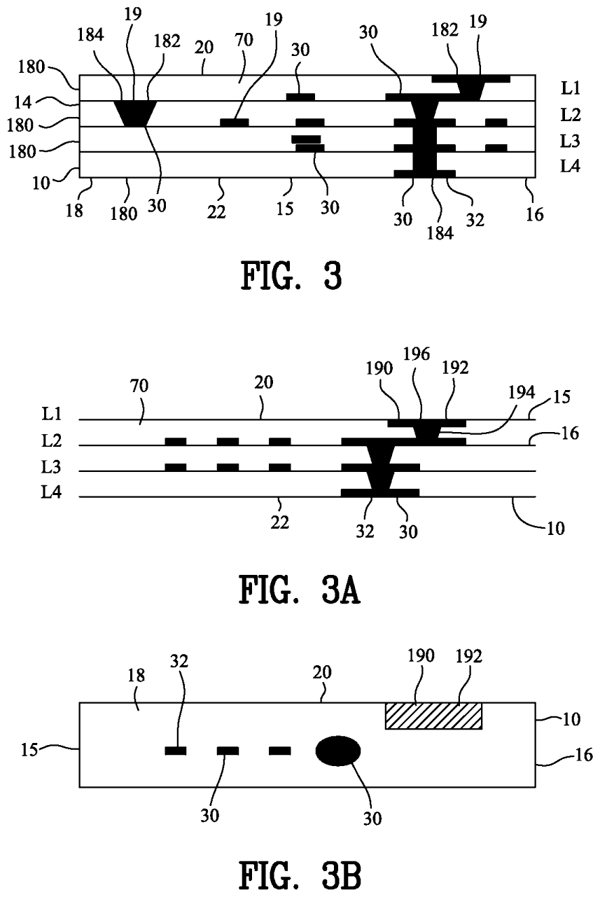

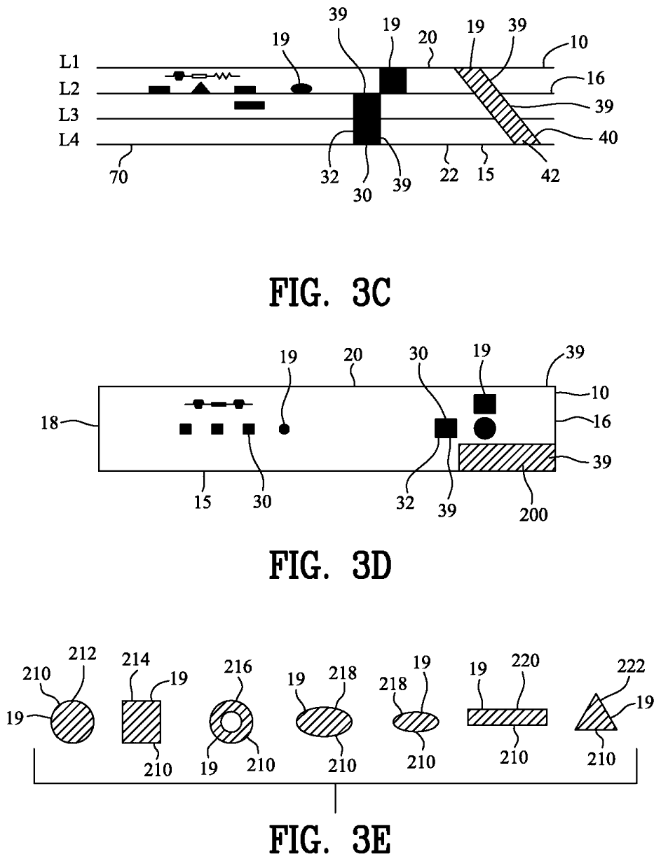

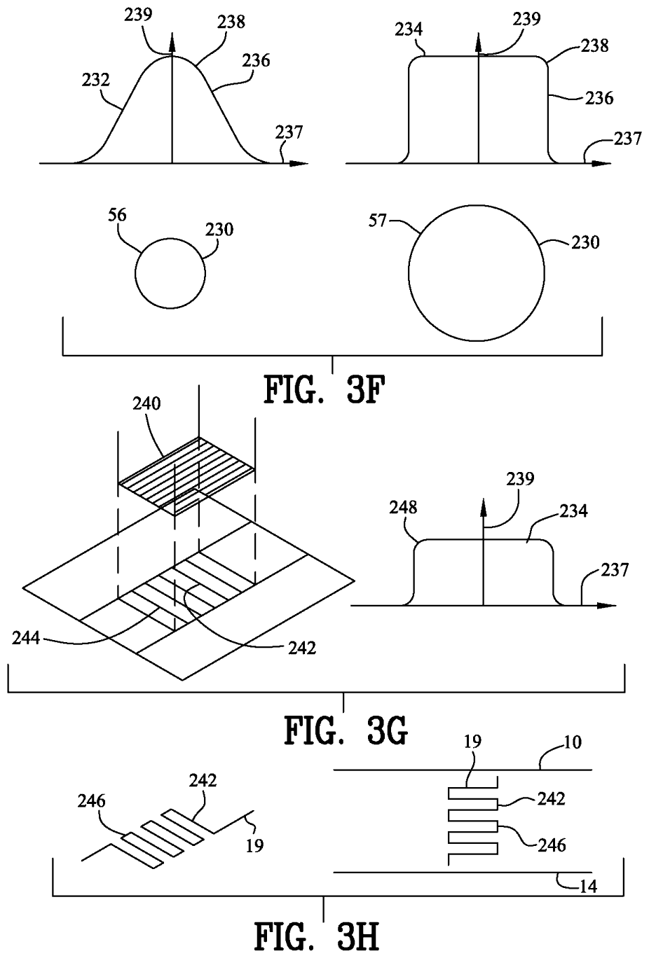

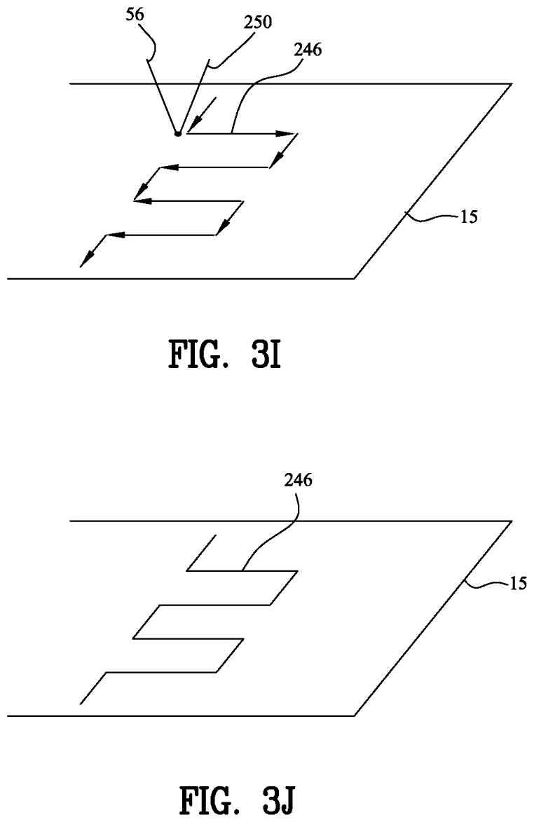

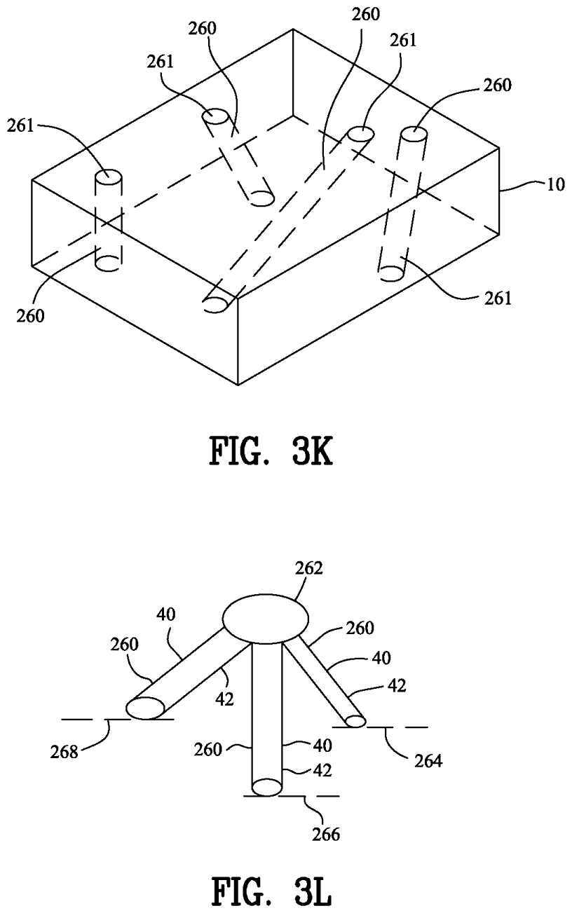

FIG. 3 is a cross-sectional view of a silicon carbide (SiC) substrate 14 wherein L1-L4 represent different interconnected layers 180 created simultaneously in the substrate materials 14 (in-situ) without any metallization additives. The areas of conversion 19 are stacked above and below via structures 30 created by laser conversion. The areas of conversion 19 which are stacked above and below may represent both electrical interconnection structures 182 and thermal interconnection structures 184.

FIG. 3A is a cross-sectional view of the state-of-the-art interconnected. FIG. 3B is a top view of layer 2 in FIG. 3A illustrating a power plane 190 plated with the copper 192, conductive copper tracers 194 and microvia 196 plated and filled with copper. FIG. 3B is a top view of FIG. 3A. FIG. 3C is a cross-sectional view of the present invention illustrating laser conversion interconnection 39. FIG. 3D is a top view of FIG. 3C illustrating laser converted 3D structure 39 through the full thickness. FIG. 3D further illustrates areas of laser converted material 39 through via structure laser converted power plan 200.

FIG. 3E illustrates different geometric shapes 210 which the laser beam 56 may create. For example, the geometric shapes 210 may include circle 212, square 214, cylindrical 216, elliptical 218, rectangle 220, triangle 222 or other shapes. More specifically, the subject invention will utilize different optical elements including but not limited to lenses, diffraction gradients, diffusers, collimators and different beam shaping techniques. These different beam shaping techniques may include but not limited to diffractive shaping techniques or refractive techniques.

FIG. 3F illustrates a first laser beam 56 and second laser beam 57 with circular cross-sections 230. Additionally the energy intensity profile 236 of the beams 56 can also be controlled either independently or in conjunction with the beam shape 238 to control the profile of the intensity distribution 239 within the cross-section of the beam 56. For example the laser beam 56 may include a Gaussian density distribution 232 or a top hat beam energy distribution 234.

FIG. 3G illustrates shutter elements 240 placed within the beam optical path which will be optimized and used to further convert the uniform laser beam 56 into various different patterns. For example, FIG. 3G includes a top hat laser beam energy distribution 234 with uniform intensity profile 248 throughout a square shaped cross-section 242 for producing a serpentine shaped shutters 244.

FIG. 3H illustrates a top hat laser beam 234 with uniform intensity profile 248 but shaped into the desired serpentine structure 244. Furthermore, FIG. 3H illustrates a top view of silicon carbide (SiC) interposer 10 or substrate 14 after radiation with the laser beam 56 creating carbon rich conductive serpentine structure 246.

FIG. 3I illustrates a similar structure which may be created in silicon carbide (SiC) 15 by direct-write a Gaussian laser beam using Galvanometer-optical elements 250. In this case one or more than one optical beam 56 may be used. FIG. 3J illustrates the resultant carbon rich conductive serpentine structure 246 created with the laser in FIG. 3I without any deposition or plating.

FIG. 3K illustrates an angular monolithic vias 260 and monolithic 3D 261 interconnecting to connect among all different surfaces of the interposer device 10. More specifically, FIG. 3K is an isometric view of FIG. 3 illustrating in-situ laser converted 3D monolithic vias 261, for example, angular monolithic vias 260 and monolithic 3D 261 interconnects created to connect among all different surfaces of the interposer device 10. FIG. 3L is a schematic of one large contact split 262 into 3 different monolithic vias 260, namely, layer 1 264, layer 2 266 and layer 3 268. Each monolithic via 260 may be created at different angels with different dimensions and is made to terminate at different layers.

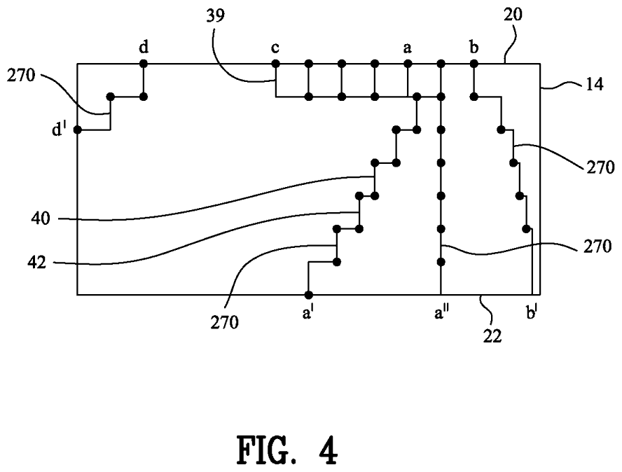

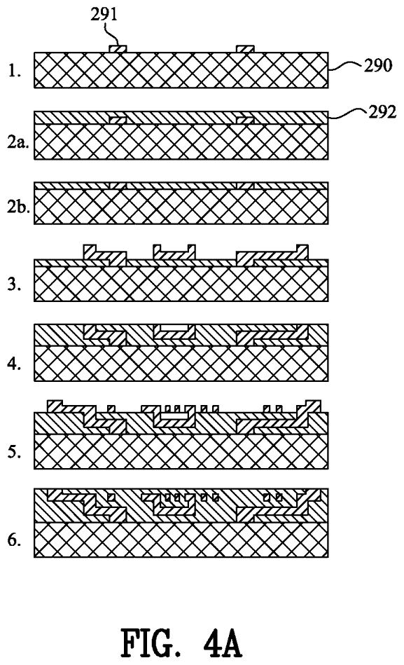

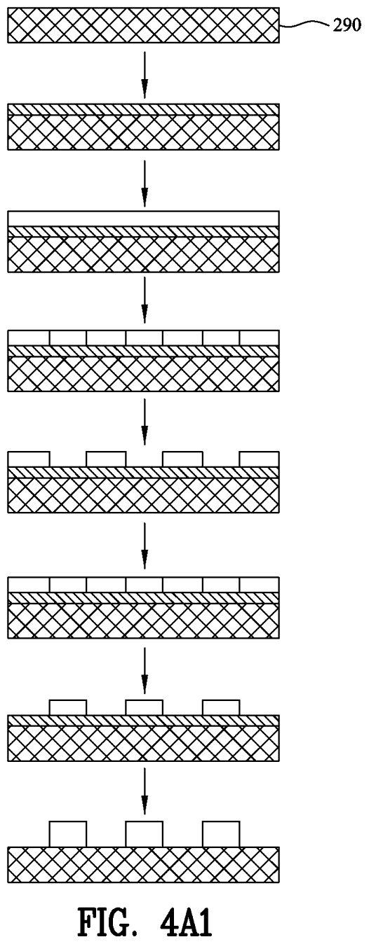

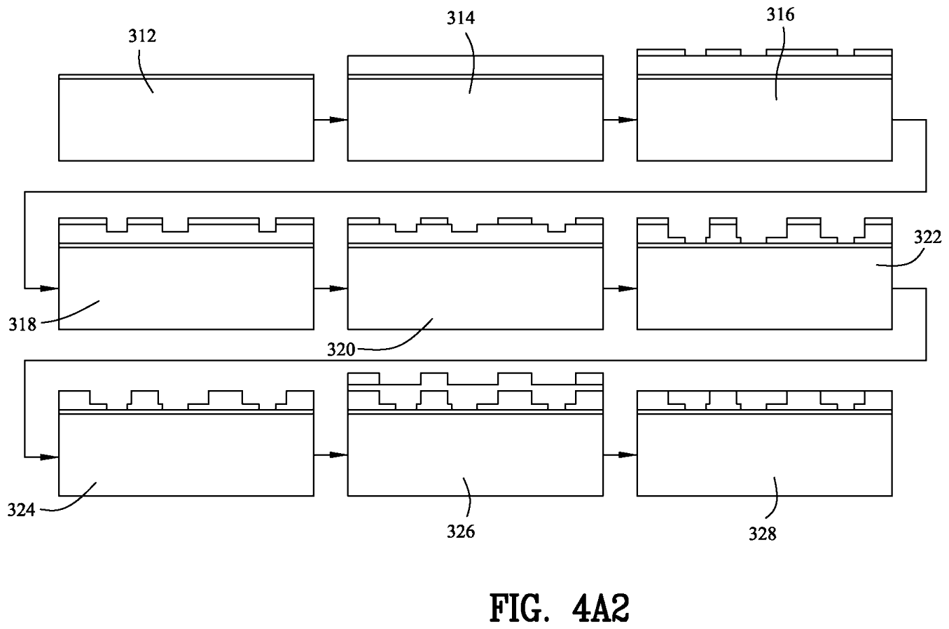

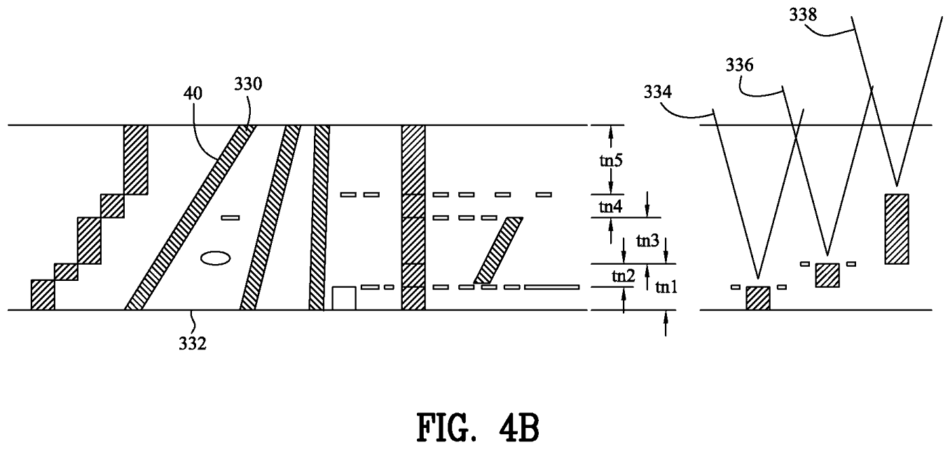

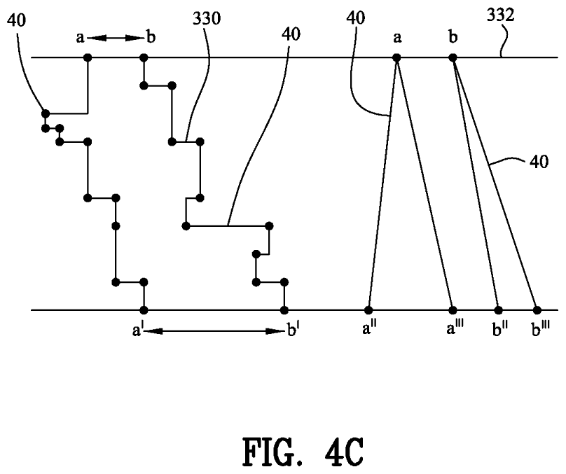

FIG. 4 illustrates the laser conversion 39 processing used throughout the full thickness and at the surfaces of the substrate 14 to create: fan out structures 270 as shown in a−a1, b−b1 wherein a−b pitch is <<a1−b1, through—via structures a−a11, surface to surface connections a-c and thermal dissipation structures d−d1. FIG. 4A and FIG. 4A1 illustrate state of the art semi addictive interconnect fabrication process 280. More specifically, FIG. 4A illustrates a damascene pattering process 282 having the substrate 290, copper 291 and dielectric 292 including steps 1, 2a, 2b, 3, 4, 5 and 6. FIG. 4A1 illustrates a semi additive pattering process 284 including providing a substrate 290, plating a thin layer of copper 291, pasting the film 294, exposuring 296, image develop 298, plating-through-hole (PTH) 300, removing the excess film 302 and etching 304. FIG. 4A2 illustrates state of the art semi additive interconnect fabrication processes 280, a dual damascene patterning process 310. More specifically, SiC deposition 312, SiO deposition 314, via pattern 316, via etch 318, metal pattern 320, metal etch 322, seed deposition 324, Cu plating 326 and Cu CMP 328.

FIG. 4B illustrates examples of the 3DR structures created laser thickness without drilling. Laser conversion 39 patterning is equivalent to quantum conversion patterning (QCP) 330. FIG. 4B includes a fill thickness “T” silicon carbide (SiC) layer 332 The layer 15 could be identified by different layer thicknesses as designated as tn1, tn2, tn3 . . . tn. The laser beam 56 conditions may be adjusted such as beam profile, focus plane, intensity to enable the conversion process at the desired depth for tn1. Simultaneously or sequentially define and irradiate a second laser beam 57 to create the conversion in the subsequent layer tn2. Similarly create layers tn3 . . . tn. All steps are created without any external material plating, deposition or doping. In addition to sequential or simultaneous layers created with laser, direct surface to surface conductive 3D structures are created at different angles 40 through the whole thickness of the silicon carbide (SiC) layer 332 A first laser beam 334 creates structure at thickness tn1. A second laser beam 336 creates structure at thickness tn2. A third laser beam 338 creates structure at thickness tn3 and tn4.

FIG. 4C illustrates a layer of silicon carbide (SiC) structure “A” 332 where in the laser quantum conversion patterning 330 creates direct 3D structure 19 throughout the thickness at variable angles 40. The flexibility to define various angles 40 and to create direct 3D interconnection structures 19 allows for higher volumetric interconnection density, overhaul miniaturization, and seamless interconnection without layer to layer interfaces reducing resistive parasitic and improving performance.

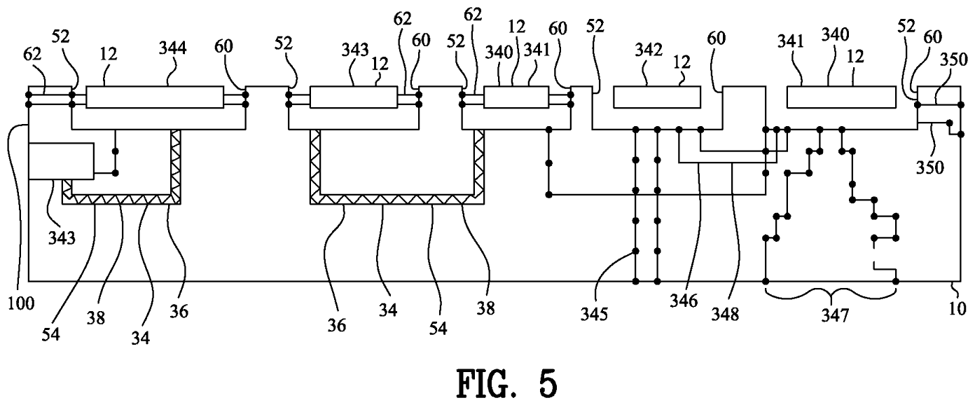

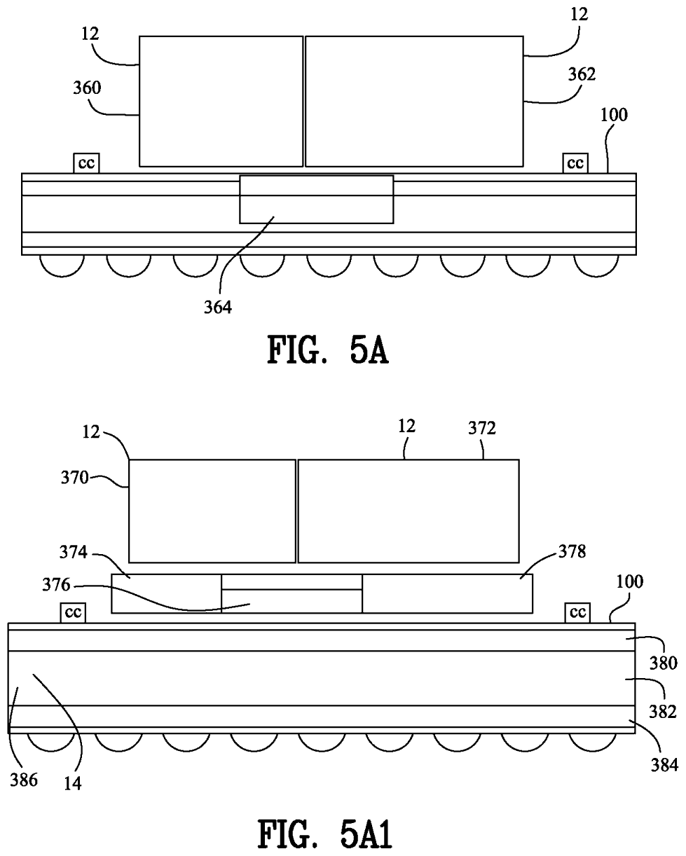

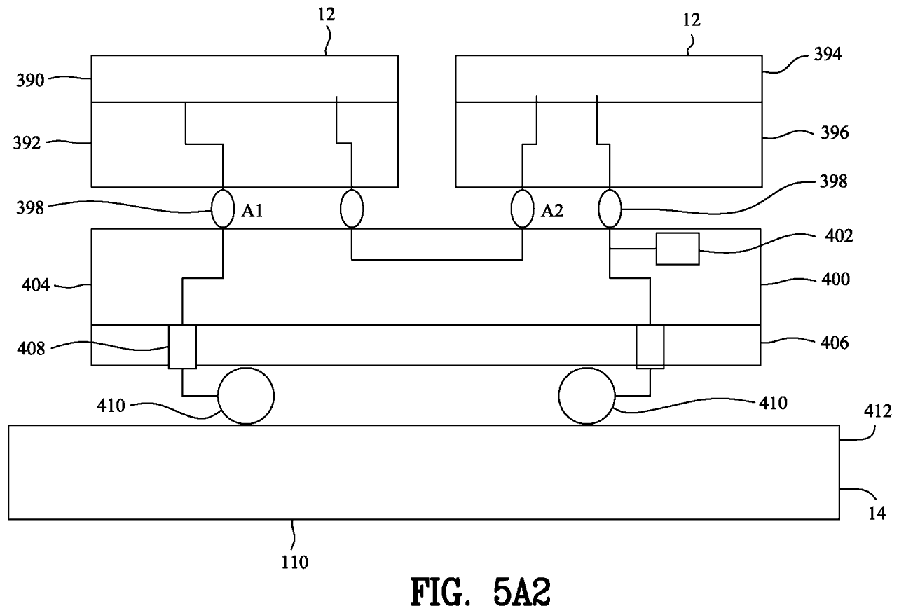

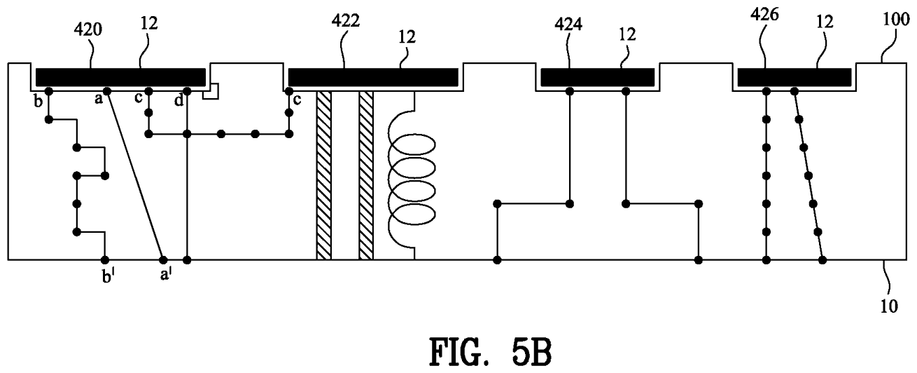

FIG. 5 illustrates a wide band gap material with machined groves housing multiple chip/chip lets with different functionality. More specifically, FIG. 5 illustrates a silicon carbide (SiC) substrate 14 prepared with machine grooves 60 housing multiple chips/chiplets 340 with different functionality, such as Si chips 341, memory chip 342, optical switch 344. The silicon carbide (SiC) substrate 14 may include optical engines 343 connected through 2.5D 19 and/or 3D integration architecture 19 using laser converted silicon carbide (SiC) 15. Additionally the substrate 14 may include optical wave guide 36 created using laser conversion connecting through silicon carbide (SiC) 15, thermal vias through silicon carbide 345, chip to chip electrical connections 346 through silicon carbide (SiC) 15, fan out structures 347 through silicon carbide (SiC) 15, and thermal connection 350 in the silicon carbide (SiC) 15 to cool the chip 340 at the sides of the groove 60.

FIG. 5A illustrates a state of the art 2.5D interconnect structures, substrate embedded 2.5D or 2.5D Bridge architecture landscape. Intel's embedded multi-die interconnect bridge (EMIB). This is an approach to do in-package high-density interconnect of heterogeneous chips. Instead of using a large silicon interposer typically found in other approaches, EMIB uses a very small bridge die with multiple routing layers. EMIB technology is an example of 2.5D packaging solution. FIG. 5A includes a HGM Die 1 360 and a GPU Die 2 362. Intel's embedded multi-die interconnect bridge (EMIB) or bridge die 364 provides localized interconnects, bridge technologies, better electrical and local parasitic capacitance.

FIG. 5A1 illustrates a state of the art 2.5D interconnect structures, elevated fanout bridge 2.5D or 2.5D Bridge architecture landscape. AMD elevated fan out bridge is a variant of the original intel embedded interconnect bridge where the very small bridge die is located not inside the package substrate but rather inside the fan out layers fabricated on top of the substrate. Both the embedded interconnect bridge (FIG. 5A) and the elevated fan out bridge are very similar in functionality and differ slightly in the manufacturing process. FIG. 5A1 includes a HBM Die 1 370, a GPU Die 2 372, a mold 1 374, a EFB 376, a Cu Pillars 378, a first top build up layer 380, a substrate core 382, a second top build up layer 384. The AMD elevated bridge 386 provides scalable solutions, lithographical v defined, standard substrates, lower costs, standard flip chip process and lower complexity bumping assembly process.

FIG. 5A2 illustrates a state of the art 2.5D interconnect structures, 2.5D Bridge architecture landscape, TSMC silicon interposer. This represents the silicon interposer architecture used by multiple device makers and fabricated primarily by TSMC (Taiwan semiconductor manufacturing company). The technology in this schematic uses a large piece of silicon with through silicon vias interconnect to connect multiple different chiplets. The through silicon interconnect are fabricated using traditional damascene process. The structure represents the state of practice in the industry and illustrate the limitation of the Si interposer architecture as a 2.5D with limited dies stacking capabilities compared with the proposed invention. FIG. 5A2 includes a first substrate 390 having a chip 1 392, a second substrate 394 having a chip 2 396. A micro bump 398 separates the chip 1 392 and the chip 2 396 from a silicon interposer 400 having a decap 402 and a tier 1 404. FIG. 5A2 further includes a substrate 406 having a TSV 408, flip chip bumps 410 and a package substrate 412.

FIG. 5B illustrates how the silicon carbide (SiC) interposer may be customized depending on the specification of each chip. The number of layers may all be created virtually through the full thickness of the interposer. For example chip 4 426 is routed using five layers, chip 3 424 is routed using two layers and chip 1 420 requires mixed routing schemes including slant via a−a1, staggered six layers routing b−b1, die to die connection c-cl and thermal dissipation interconnection d−d1. Chip 2 422 is illustrated with various passive elements created using laser conversion patterning or quantum conversion patterning (QCP). Also constructed within the silicon carbide (SiC) interposer as shown in FIG. 5B includes a resistor, inductor and capacitor. Depending on the specifically of each chip, the silicon carbide (SiC) interposer may be customize the # of layers. All layers are created virtually through the full thickness of the Interposer structure (in one Embodiment of the Invention).

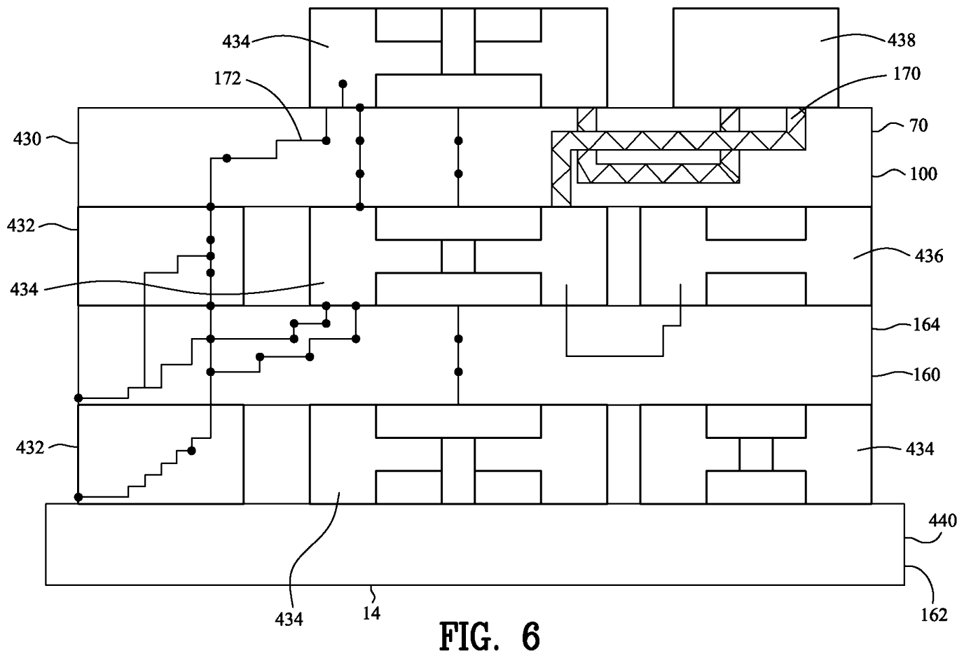

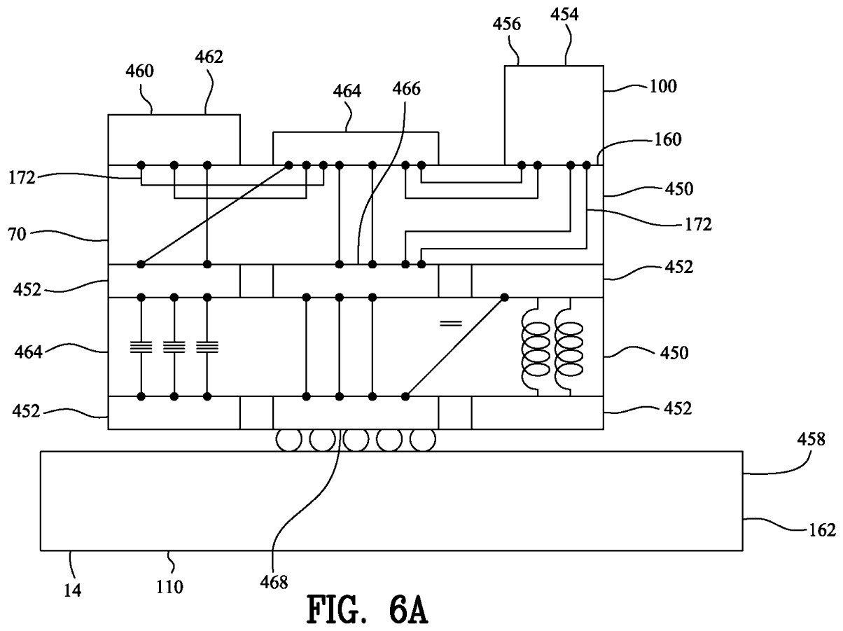

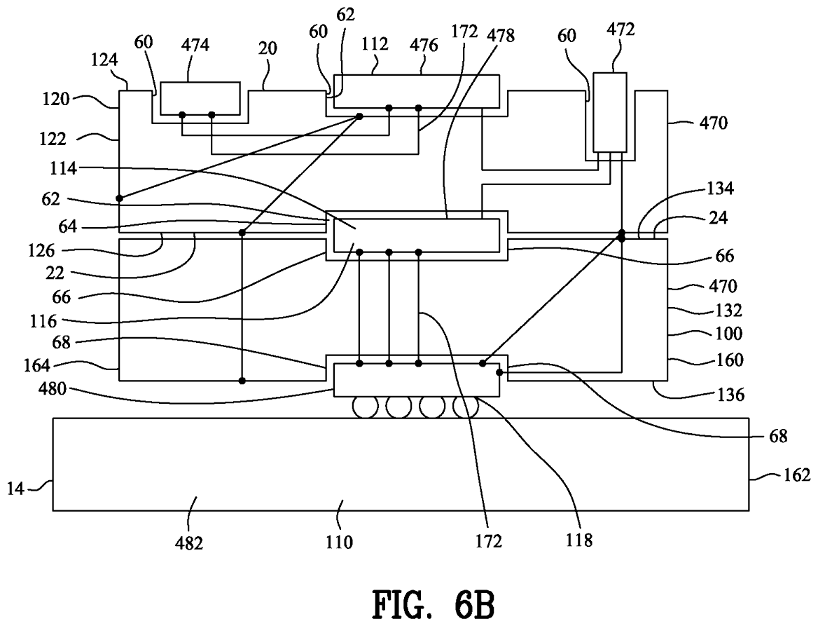

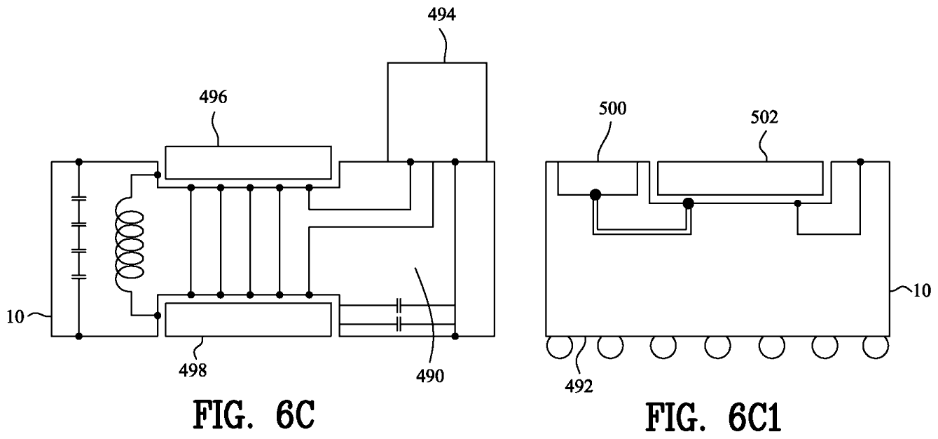

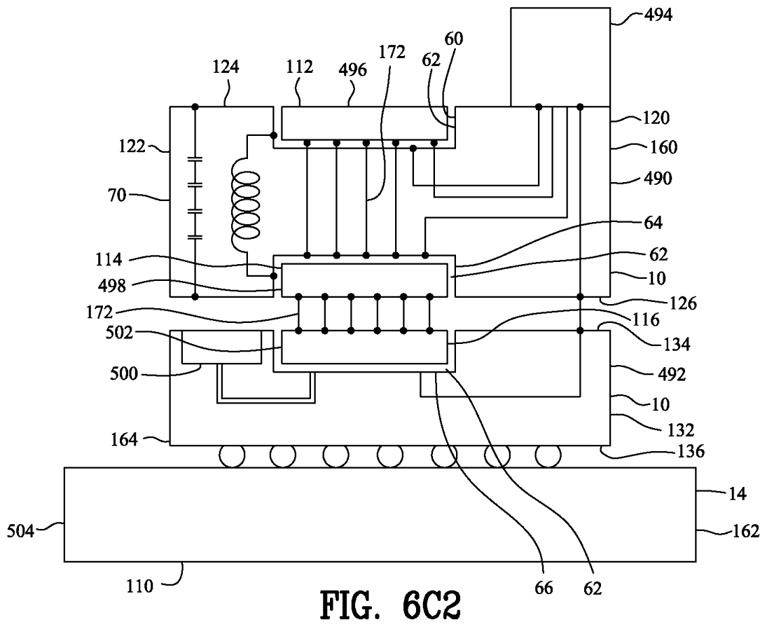

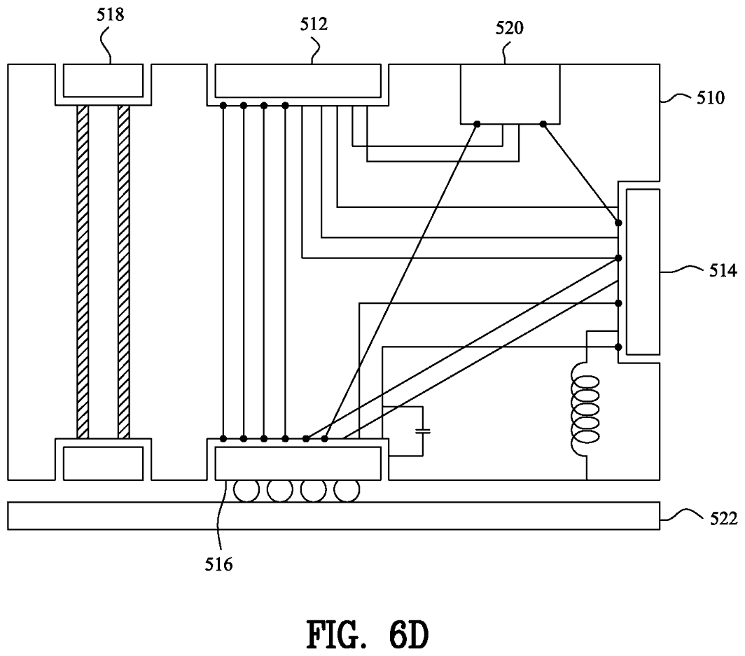

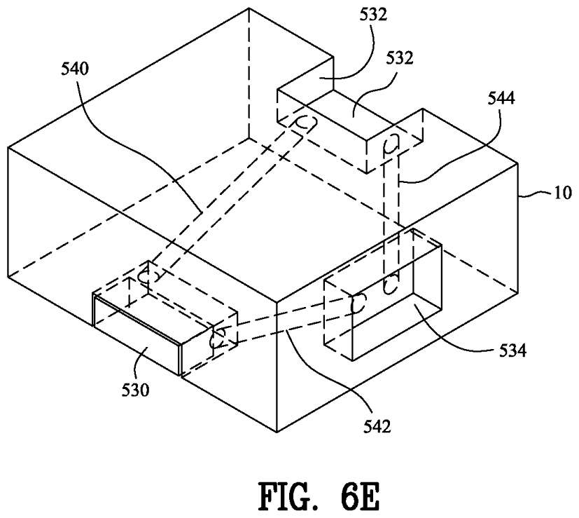

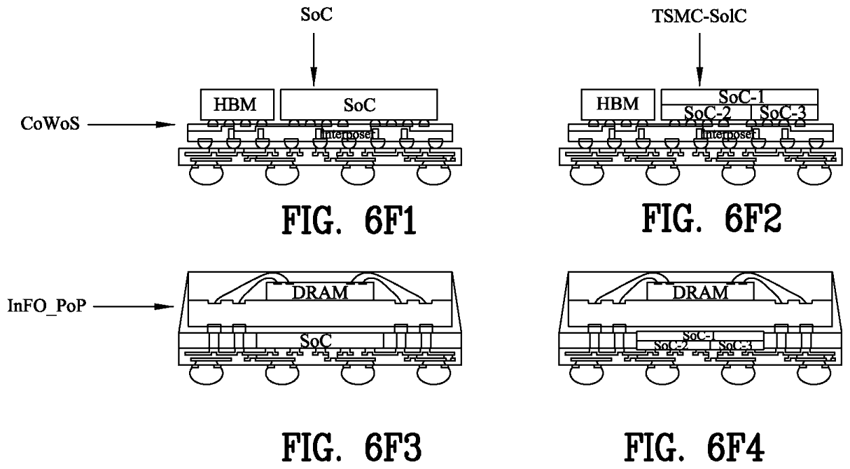

FIG. 6 illustrates a 3-D integration on laser converted silicon carbide (SiC) interposer 430 and silicon carbide (SiC) Thermo chip(s) 432 coupled to a packing substrate 440. The converted system includes chips with various functionalities including but not limited to Si-chips 434, memory chips 436, optical chips, switch or component 438, Thermo chips 432 and various other examples.

FIG. 6A illustrates an architecture option including a laser converted silicon carbide (SiC) interposer 450, a laser converted silicon carbide (SiC) Thermo chips 452 and a substrate 458. The HBM 454 may include a memory chip 456, the optical 460 may include an optical chip/engine 462 and the SoC 464, SoC 466 and SoC 468 may include logic chips 464, 466 and 468 respectively.

FIG. 6B illustrates an alternative architecture option illustrating a substrate 482 and a compact structure using machined silicon carbide (SiC) interposer 470 for eliminating the need of silicon carbide (SiC) Thermo chips. The HBM 472 may include a memory chip, the optical may include an optical chip/engine 474 and the SoC 476, SoC 478 and SoC 480 may include logic chips 476, 478 and 480 respectively.

FIGS. 6C, 6C1 & 6C2 illustrate simultaneous fabrication of QCIA (Quantum Conversion Integration Architecture) architecture enabling accelerated run rate an improved yield on a substrate 504. FIG. 6C illustrates that two different QCIA designs (QCIA 1 490 in FIG. 6C1 and QCIA 2 492 in FIG. 6C2) that are being combined to form the 3D stacked QCIA architecture illustrated in FIG. 6B, the process, material and approach proposed in this invention allows for the creation of the two separate parts FIG. 6C1 and FIG. 6C2 in parallel then subsequently assembly them on top of each other to produce the 3D architecture shown in FIG. 6B. This is a unique and differentiating feature for the proposed invention in comparison with the state of practice shown in FIGS. 5A, A1 and A2. QCIA 1 490 in FIGS. 6C1 & 6C2 includes a HBM 494, SoC1 496 and SoC2 498. QCIA 2 492 in FIGS. 6C1 & 6C2 includes an optical chip/engine 500 and SoC3 502.

FIG. 6D illustrates a customized point to point connection using QCIA (Quantum Conversion Integration Architecture) architecture and laser conversion patterning or quantum conversion patterning (QCP) which results in a power efficient and thermally enhanced integration architecture with a compact footprint design and higher-speed interconnection. All the chiplets are independently cooled and thermally managed for maximizing system energy efficiency. This architecture much increases density (connection/mm\hat{ }3). Due to the ability to create 3D angular monolithic vias, this architecture introduces new metric into the 3D-integration, namely, the volumetric density (number of connection/mm\hat{ }3) rather than the standardized industry density (number of concentration/area). The QCIA 510 in FIG. 6D includes SoC1 512, SoC2 514, SoC3 516, an optical chip/engine 518, HBM 520 and substrate 522.

FIG. 6E is an isometric view of FIG. 6 illustrating 3D integration of multiple integrated circuits chips connected at different faces of the silicon carbide (SiC) interposer. Microchip 1 530 is positioned inside a recess created to have the microchip 1 530 at one side of the interposer 10. Microchip 2 532 is positioned inside a recess created to have the microchip 2 532 at another side of the interposer 10. Microchip 3 534 is positioned inside a recess created to have the microchip 3 534 at another side of the interposer 10. A first angular monoloithic vias 540 connects the microchip 1 530 with the microchip 2 532. A second angular monoloithic vias 542 connects the microchip 1 530 with the microchip 3 534. A third angular monoloithic vias 544 connects microchip 2 532 with microchip 3 534.

FIGS. 6F1, 6F2, 6F3 and 6F4 illustrate state of the art 3D interconnect structures. FIGS. 6F1, 6F2, 6F3 and 6F4 are a summary illustrating the current state of practice in the industry for attempting to offer die stacking. All 4 different architectures illustrated in the schematics have the same limitation of no more than two die stacks. This is a fundamental differentiation with the proposed invention. Using the material and proposed process in our invention, we are able to stack more than 3 dies and offer the thermal and power delivery solution to support that high die stack designs.

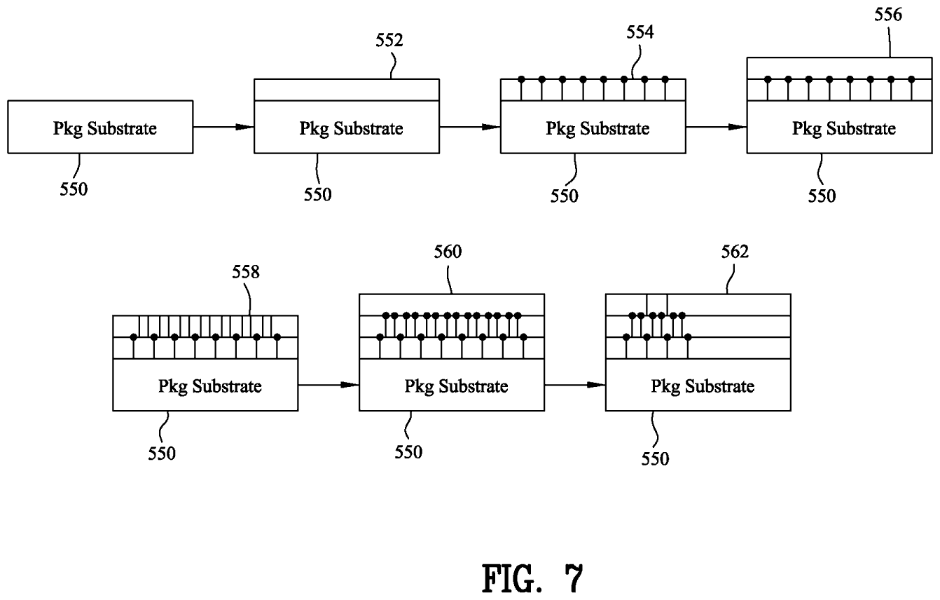

FIG. 7 illustrates the option for in-situ deposition and patterning of QCIA on organic substrates. More specifically, FIG. 7 illustrates the direct formations of redistribution layers on packaging substrate for heterogeneous integrated applications. Each layer is deposited then laser converted to form the pattern before the substrate layer is deposited. The steps in FIG. 7 include providing a packing substrate 550, low temp deposited material (SiC) or carbine like diamond 552 onto the packing substrate 550, laser conversion putting of the deposited layer 554, subsequent layer deposition 556, subsequent layer is laser converted 558, third layer is deposited 560, third layer is converted completing the overall redistribution or fan-out structure 562.

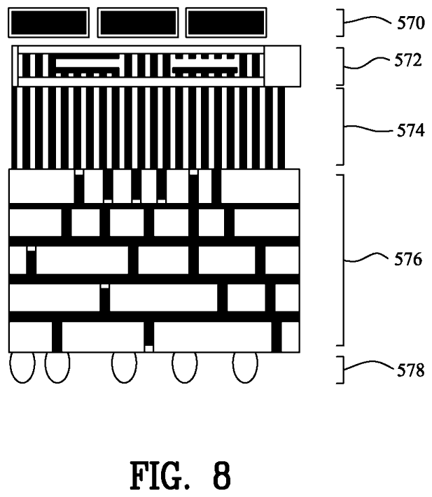

FIG. 8 illustrates an architecture option for the improved interposer showing multiple different redistribution layers on both sides of the interposer outer surfaces. FIG. 8. Illustrates the option for formation of multiple redistribution layers of varied number, dimensions functionality and materials type on both sides of the interposer outer surface. More specifically, the interposer 10 in FIG. 8 includes a IC-chiplets 570, chiplets routing/redistribution layer 572, a QCI interposer 574, fan out and redistribution layer 576, QCI interposer fan-out pitch 578.

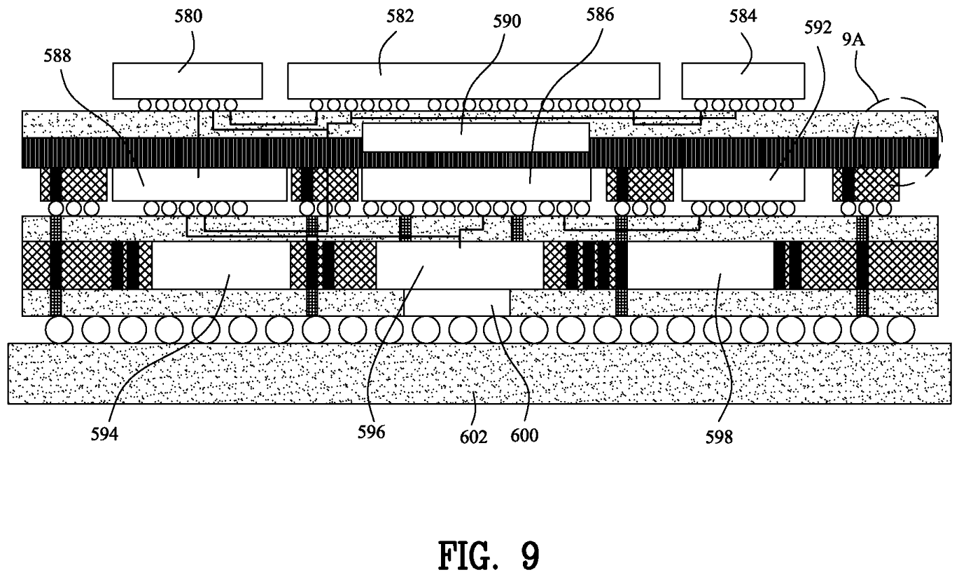

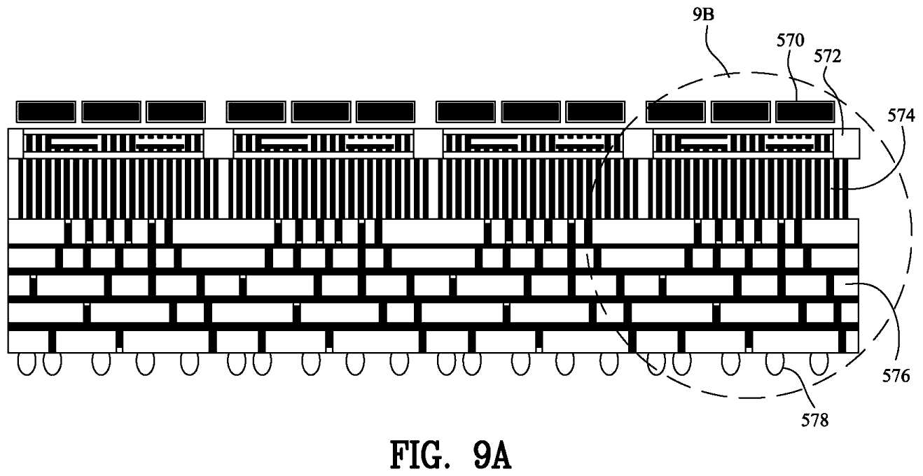

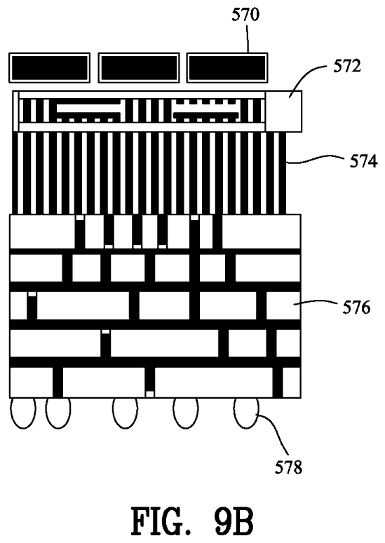

FIG. 9 illustrates an architecture option for the improved packaging device in which the improved interposer shown in FIG. 8 is further assembled a top of a high density interconnect substrate. The high-density interconnect illustrated in FIG. 9 is comprised of multiple build up layers formed on both sides of the outer surfaces of a SiC core structure formed with the laser irradiation conversion process and laser drilling. The QCIA performance is optimized for energy efficient high-performance computing. FIG. 9 includes an optical Xvr 580, XPU2 582, DRAM 584, OCIA interconnect Structure 586, Si Ivr II 588, XPU1 590, second DRAM 592, BIST/control 594, Power FET 1 596, QCIA substrate 598, Si IVR I 600 and System PBC 602.

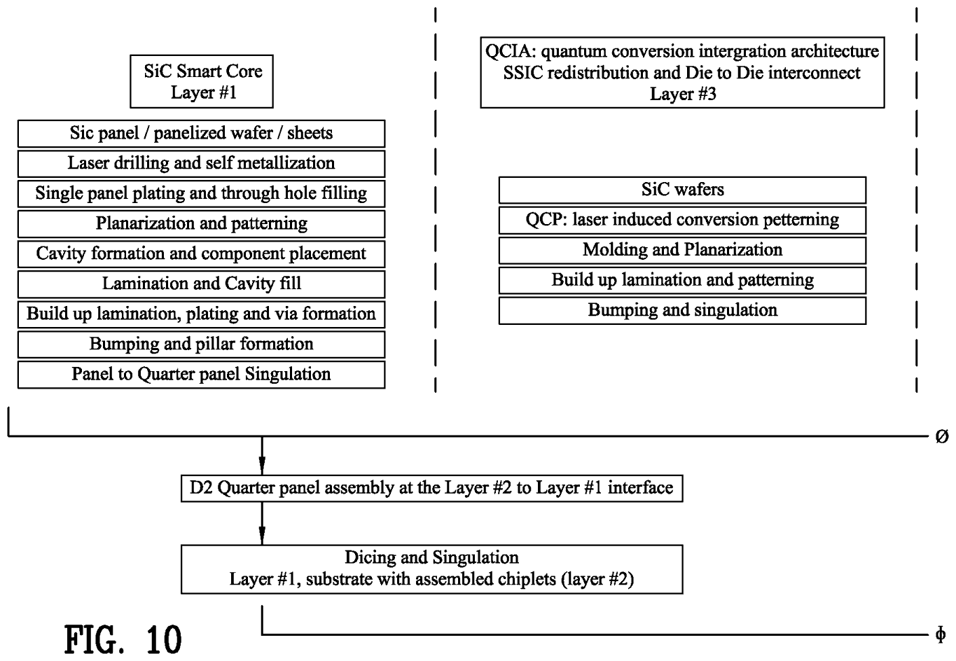

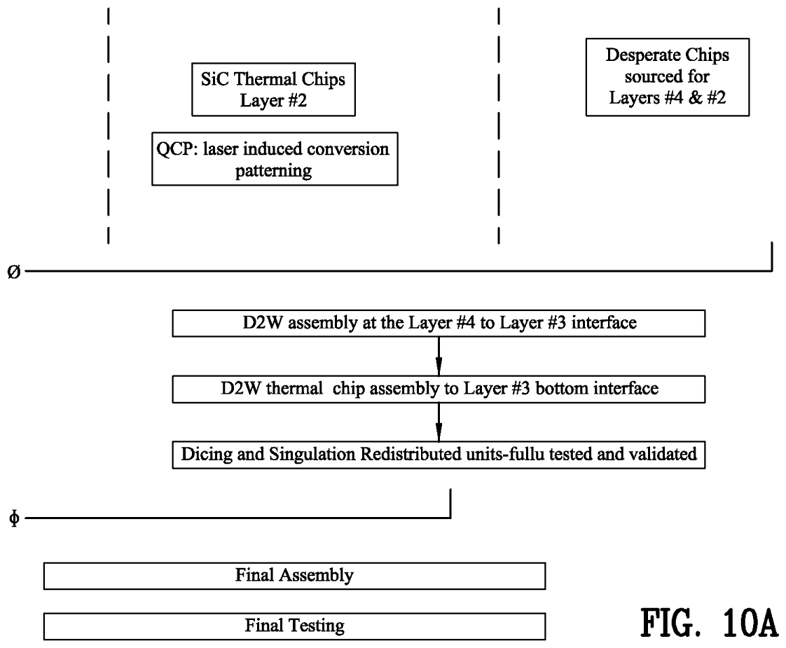

FIGS. 9A and 9B are a detailed schematic showing a higher magnification of the QCIA interconnect structure 586 shown in FIG. 9. In this illustration, the QCIA interconnect structure 586 consists of a SiC interposer 604 with QCP interconnects 606 featuring one die to die interconnect layer on top 608 and five (5) fan out build up layers on the bottom 610. FIGS. 10 and 10A illustrate the parallel processing nature of assembling the different layers illustrated in FIG. 9.

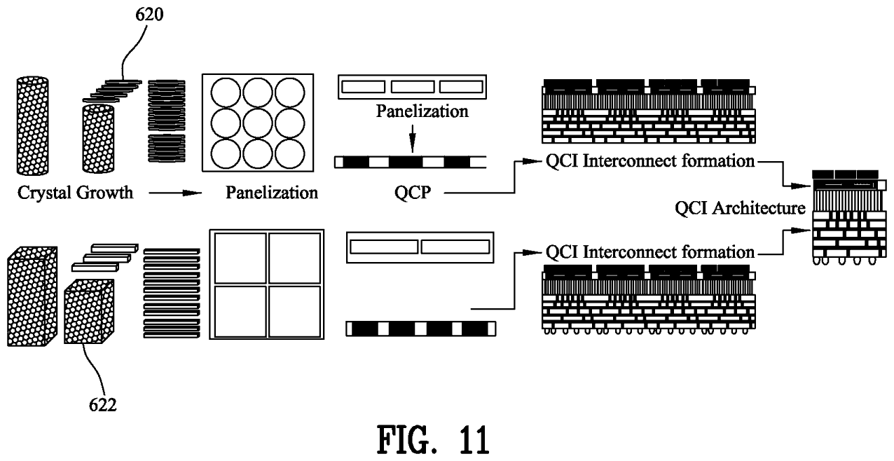

FIG. 11 illustrates the method of making the improved interposer with multiple redistribution layers using two different variations of the process of fabrication. In one embodiment the fabrication process uses SiC in a wafer format 620 in another embodiment the fabrication process uses SiC in square quarter panel size format 622. FIG. 11 illustrates the detailed process of transforming both the wafer format SiC 620 and the quarter panel format SiC 622 into full panel size making them compatible with widely used panel manufacturing processes for high density interconnect substrate fabrication infrastructure.

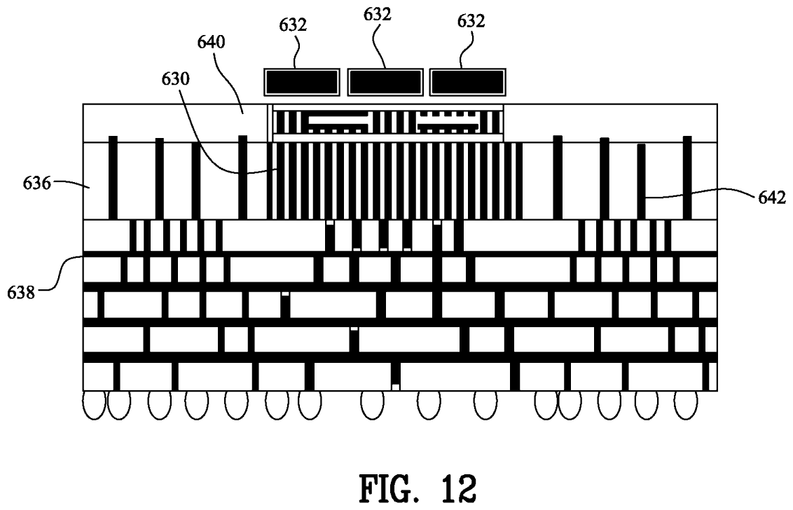

FIG. 12 is a schematic representation of a single unit of the QCIA interconnect structure 630 including a hybrid glass SiC interposer featuring 3 chiplets 632 connected side by side on top of the QCIA interconnect structure 630 with one die to die interconnect layer on top of the SiC interposer and five (5) fan out layers on the bottom side. The QCIA interconnect structure 630 further includes a RDL layer 640 on top of both Glass and SiC hybrid interposer and TGV through glass via 642.

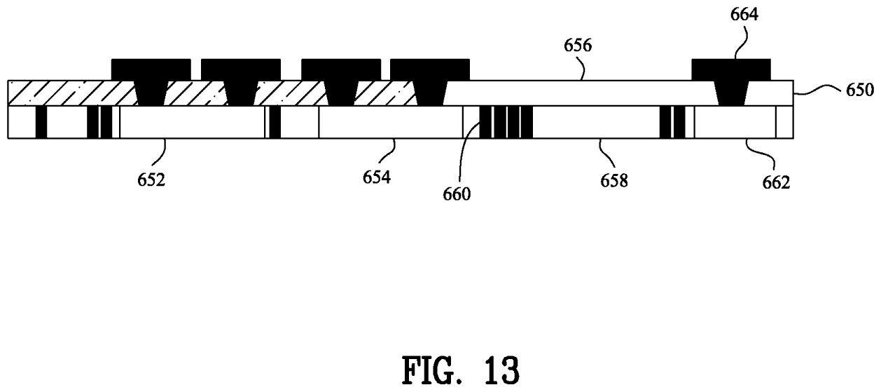

FIG. 13 is an illustration schematic of a substrate core structure made possible using the proposed quantum conversion patterning process and materials set. The structure of the core module features SiC with embedded power, active and passive device elements. The QC-Core have interconnect through hole structures created using the quantum conversion patterning process. The combined choice of the base material (SiC, Si3N4, AlN or a hybrid structure of all three) plus the highly conductive laser converted structure make the QC-Core module a unique power delivery and thermal management circuit element that could function on its own as a power package device or could subsequently be integrated into organic packaging device or Silicon based device for further system level integration. More specifically, the QC-Core 650 structure may include a control device 652, a power device 654, a polymer material layer 656, a QCIA substrate core material 658 such as SiC, Si3N4 or hybrid, a OCIA interconnect 660 created in situ within SiC or Si3N4, a passive 662 and copper metallization 664.

The subject invention further incorporates the following:

A microelectronic interposer with double sided redistribution layers used for multiple chips interconnection and fan out of electronic circuitries. (QCIA interposer).

Stackable and reconfigurable microelectronic system featuring the QCIA interposer and high density interconnect substrates manufactured using the proposed invention (a 3D heterogeneous integration architecture built using the proposed invention).

Substrate with power delivery and thermal management modules fully integrated into the substrate structure and fabricated using the QCP process eliminating the need for electroless metallization.

Thermal Chip: a wide bandgap material such as SiC with thermal conduction pathways in-situ fabricated through the thickness, at the surface and across the edges of the Chip to conduct heat and dissipate the thermal energy generated at multiple levels of the system.

Power delivery modules such as power converters built in a wide bandgap materials such as SiC using the Quantum conversion pattering process and placed at multiple stack locations in the microelectronic system.

Thermal management Modules such as power converters built in a wide bandgap materials such as SiC using the Quantum conversion pattering process and placed at multiple stack locations in the microelectronic system.

A substrate core device where SiC or other wide bandgap material is used and patterned using laser conversion irradiation and/or laser drilling to form the interconnect within the core structure.

A substrate core device where SiC or other wide bandgap material is used and patterned using laser conversion irradiation and/or laser drilling to form the interconnect within the core structure. The core device is made to incorporate the power delivery modules and the thermal management modules.

Example of the laser processing parameters to induce the quantum conversion patterning Single crystal 4H—SiC wafer with polished ˜0001!-Si face is used in this study for fabricating the nanoribbons/SiC structure. The wafer has a low-doped (531015 cm23 625%), n-type, 10 mm˜61.0%! thick epilayer grown onaxis @ (0001)60.25°# over a 50.8 mm diameter 4H—SiC substrate. To fabricate the C-rich SiC nanoribbon, laser irradiation experiments were conducted using a Q-switched Nd:YAG laser of wavelength 1064 nm. 1 mm wide and 7 mm long region was irradiated with laser pulses of repetition rate f535 kHz, pulse duration ˜on-time! t P5260 ns, pulse energy EP50.6 mJ/pulse, laser beam diameter D51 mm, and laser scanning speed V55 mm/s. This region was irradiated three times in a nitrogen ambient ˜1 atm! before taking the sample out of the processing chamber. The incident fluence of a single pulse, which is given by fP5Ep/Ai, where Ai is the irradiated area given by Ai5(pd2/4)1DVt P for a circular spot, is found to be 76.4 mJ/cm2 and the pulse intensity, which is given by I p5(fP/t P), is 293.3 kW/cm2. However, a fraction of this energy is absorbed by the work piece because the transmittance and reflectance of the 4H—SiC sample used in this study were measured to be 0.4 and 0.15, respectively, at 1064 nrn wavelength. 14 Focused ion beam ˜FIB!milling was used to prepare 5 mm38 mm31200 Å section of the laser-irradiated 4H—SiC wafer for microscopic studies. High-resolution transmission electron microscope ˜HRTEM!, Techni F 30, equipped with a windowless Link energy dispersive spectroscopy ˜EDS! analyzer was used to study the laser-fabricated nanostructure and to obtain selected area electron diffraction ˜SAED! patterns for different regions in the laser-treated wafer.

Additional experimentation was also conducted using different laser wavelength to create conversion sin the SiC materials. these wavelength examples are 193 nm, 532 nm, 532 nm wavelength laser with femto second pulse width.

Example of commercially available build up polymeric film used for fabricating the redistribution and/or the build up layer used on top and below the QCIA Interposer. The most commonly used microfilm materials for build up circuit fabrication in advanced packaging is Ajinomoto Build up Film (https://www.ajinomoto.com/innovation/action/buildupfilm). In fact, Ajinomoto Build-up Film (ABF) can be found at the heart of most of the world's personal computers, where it provides electrical insulation of complex circuit substrates for high-performance central processing units (CPUs). These films comes in multiple different versions across a wide array of electronic materials properties, thermo mechanical properties and geometrical dimensions (i.e., film thickness, film thickness variation, width)

The table below offer some example of the available varieties of these materials:

Ajinomoto Build-up Film ® (ABF)

| Variety | Features |
|---|---|
| GX-92 | Standard |
| GX-T31 | Low surface roughness, Low CTE |
| GZ-41 | Low surface roughness, Low CTE, High Tg |
| GL-102 | Low surface roughness, Low dielectric |
| | loss tangent, Low CTE, High Tg |

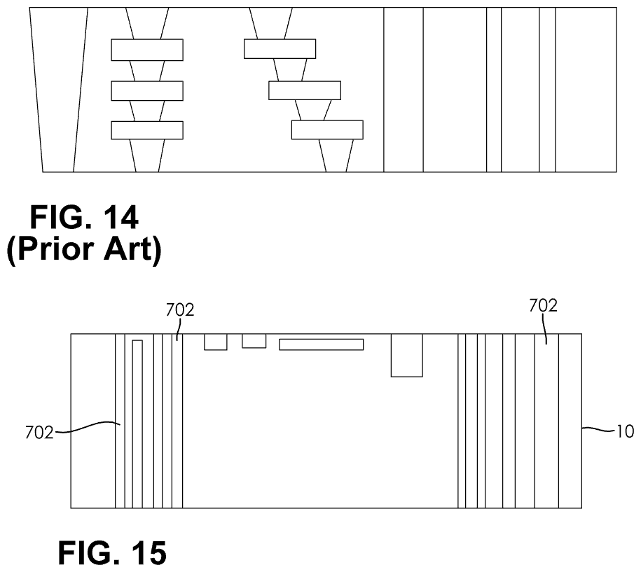

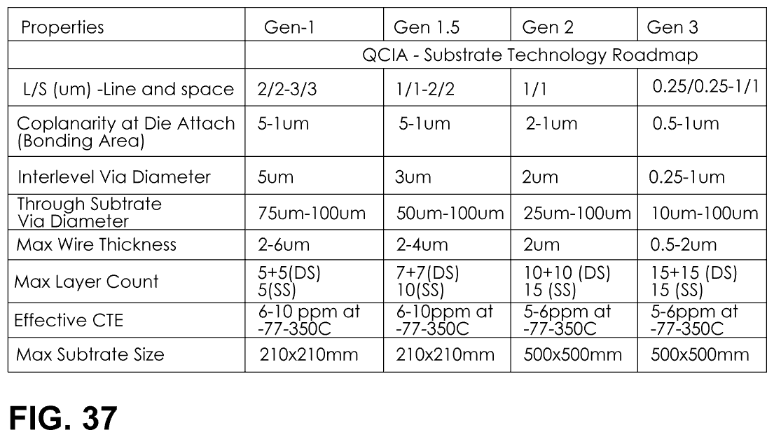

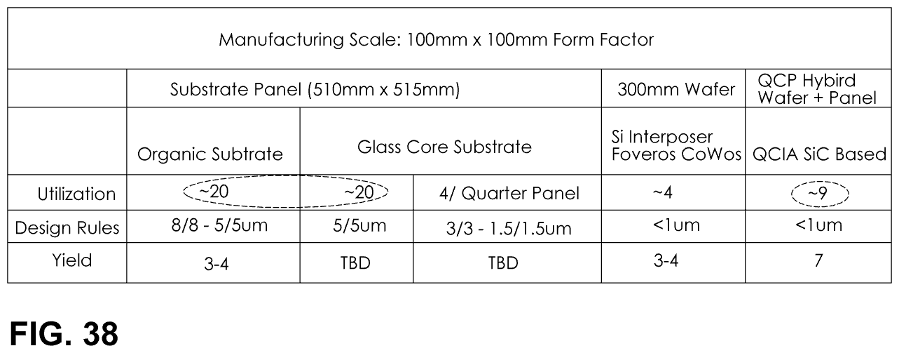

FIGS. 15-39A illustrate the subject matter of the continuation in part patent application. FIG. 14 illustrates a current prior art interposer wherein the interconnect requires etching, deposition, CMP and only permits vertical directions for the interconnects. FIGS. 15-39A illustrate an architecture and method of making a system level semiconductor IC-substrate, interconnect fabric and integrated electronic systems 700.

System level semiconductor IC-substrate, interconnect fabric and integrated electronic systems 700 introduces novel structure and manufacturing steps and a more simplified architectural variants to enable the usage of QCIA to form a system level IC-substrate and hence the formation of a 3D/2.5D electronic system with less disruption to the manufacturing flows used today in high volume manufacturing fabs. The inventive steps specific to this application includes; the deposition of SiC film materials—both directly and through a transition/adhesion promotion layers atop various materials commonly used today in electronic system applications. The deposition step is then followed by the QCP process (quantum conversion patterning process) to form the interconnect layers within the deposited SiC. The deposited SiC layer is electrically connected to the underlaying material (Si, Glass or organic composite material) and the overall structure is layered in repetition to form a system level substrate. Included within the system level substrate architecture, several variation of QCIA structures that provide different circuitry functions including but not limited to; (1) 2.5 QCIA interconnect bridge, QCIA interconnect bridge with built in capacitors, QCIA interconnect bridge with through SiC vias formed either by the QCP process or using traditional damascene, dual damascene or semi additive patterning processes. (2) QCIA interconnect layer deposited in conjunction with waveguides prefabricated in glass and/or Silicon materials to formulate a hybrid optoelectronic connections. (3) QCIA Interconnect layer deposited in conjunction with integrated localized interconnect elements that are either prefabricated and then embedded within the redistribution layer or in-situ fabricated within the redistribution layers.

The system level semiconductor IC-substrate, interconnect fabric and integrated electronic systems 700 includes an improved semiconductor IC substrate 710 for supporting and interconnecting integrated circuit die 112 or multiple dies 112 comprises a silicon carbide (SiC) interposer 10 having a first outer surface 20 and a second outer surface 22. A plurality of interposer connectors 30 are formed in situ within the silicon carbide (SiC) interposer 10. A dielectric layer 712 has a first outer surface 714 and a second outer surface 716. A plurality of electrical connectors 718 are formed within the dielectric layer 712. An interface 720 is between the second outer surface 22 of the silicon carbide (SiC) interposer 10 and the first outer surface 714 of the dielectric layer 712 for electrically connecting the plurality of interposer connectors 30 to the plurality of electrical connectors 718.

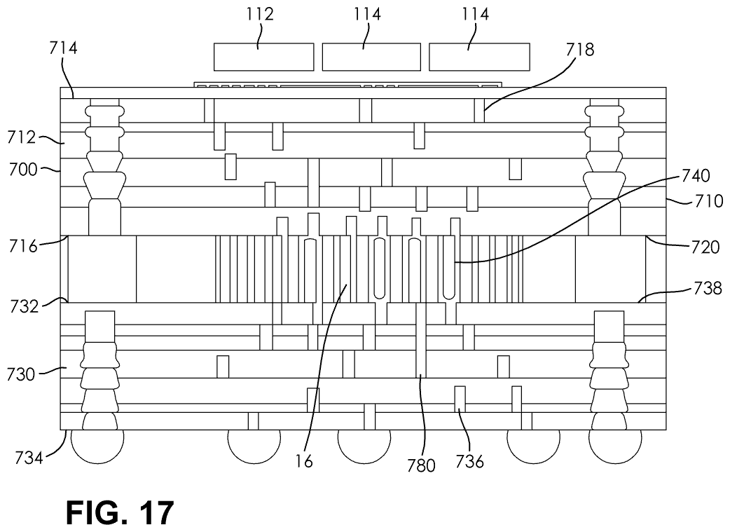

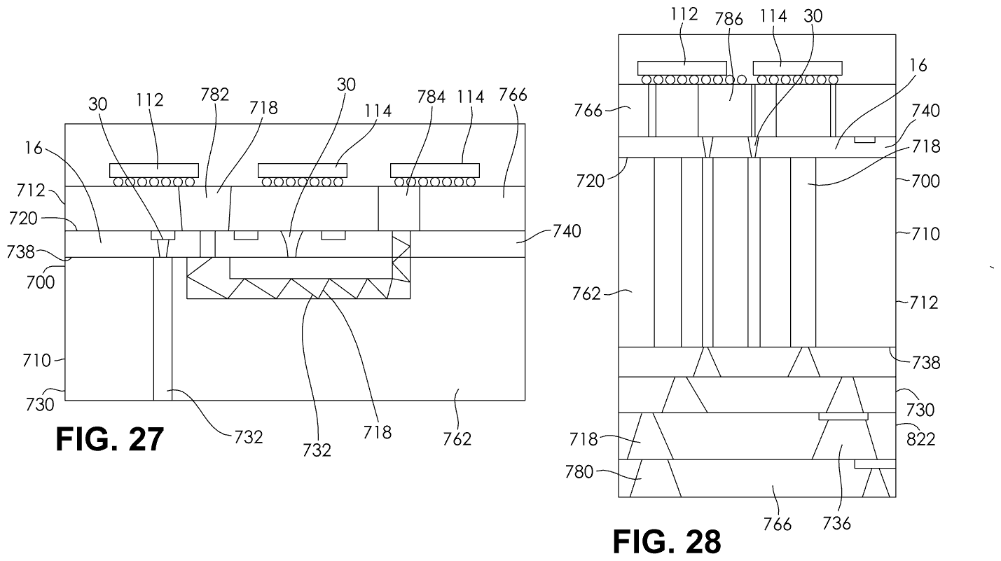

As best shown in FIGS. 17 and 27, the second outer surface 22 of the silicon carbide (SiC) interposer 16 abuts the first outer surface 714 of the dielectric layer 712. A second dielectric layer 730 has a first outer surface 732 and a second outer surface 734. A second plurality of electrical connectors 736 are formed within the second dielectric layer 730. A second interface 738 is between the first outer surface 714 of the silicon carbide (SiC) interposer 16 and the second outer surface 734 of the second dielectric layer 730 for electrically connecting the plurality of interposer connectors 30 to the second plurality of electrical connectors 736. The silicon carbide (SiC) interposer 16 is interposed between the dielectric layer 712 and the second dielectric layer 730 defining a silicon carbide (SiC) interposer core 740.

The plurality of interposer connectors 30 include carbon electrical connectors 32 formed by laser irradiation of the silicon carbide (SiC) to form the carbon electrical connectors 32.

The plurality of interposer connectors 32 may include are carbon portions 750, carbon vias 752, graphene portions 754, graphene vias 756 or optical wave guide connectors 34 formed by a tunnel 36 in the silicon carbide (SiC) by carbon rich tunnel walls 38.

The dielectric layer 712 may include but not limited to silicon 760, glass 762, organic composite material 764, or polymeric material 766. The dielectric layer 712 may alternatively include a combination of silicon 760, glass 762, organic composite material 764, or polymeric material 766.

As shown in FIGS. 15-39A, the plurality of electrical connectors 30 may include, but not limited to, passive electrical components 770, active electrical components 772, electrical conductive portions 774, electrical conductive vias 776, electrical conductive plated though holes 778, redistribution conductive channels 780, input coupler 782, output coupler 784, integrated localized interconnect structure 786, embedded bridges 788, embedded thermal CHIPS 790 or optical wave guide connector 34 formed by a tunnel 36 in the dielectric layer 712. The interface 720 may include, but not limited to, direct abutment 722 and/or adhesive 724.

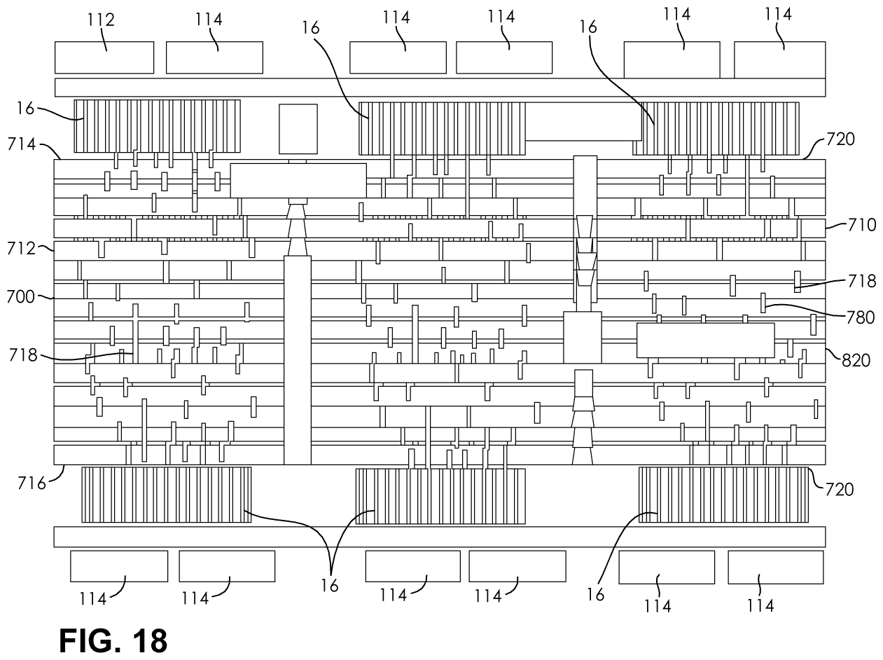

As shown in FIG. 18, the second outer surface 22 of the silicon carbide (SiC) interposer 16 abuts the first outer surface 714 of the dielectric layer 712. A second silicon carbide (SiC) interposer 800 has a first outer surface 802 and a second outer surface 804. A second plurality of interposer connectors 806 is formed in situ within the second silicon carbide (SiC) interposer 800. A second interface 808 is between the first outer surface 802 of the second silicon carbide (SiC) interposer 800 and the second outer surface 716 of the dielectric layer 712 for electrically connecting the second plurality of interposer connectors 806 to the plurality of electrical connectors 736. The dielectric layer 712 is interposed between the silicon carbide (SiC) interposer 16 and the second silicon carbide (SiC) interposer 800 for defining a dielectric layer core 810.

FIG. 18 further illustrates a first integrated circuit die 112 electrically coupled to the first outer surface 20 of the silicon carbide (SiC) interposer 16. An second integrated circuit die 114 is electrically coupled to the second outer surface 804 of the second silicon carbide (SiC) interposer 800. The first integrated circuit die 112 abutting the first silicon carbide (SiC) interposer 16 and the second integrated circuit die 114 abutting the second silicon carbide (SiC) interposer 800 defines a double-sided assembly of chiplets 820.

As shown in FIG. 25, the dielectric layer 712 includes a glass layer 762 and a polymeric layer 766. The glass layer 762 is interposed between the silicon carbide (SiC) interposer 16 and the polymeric layer 766 for defining a hybrid dielectric layer 822.

As shown in FIG. 26, the dielectric layer 712 includes a silicon layer 760 and a polymeric layer 766. The silicon layer 760 is interposed between the silicon carbide (SiC) interposer 16 and the polymeric layer 766 for defining a hybrid dielectric layer 822.

As shown in FIG. 28, the dielectric layer 712 includes a glass layer 762, a first polymeric layer 766 and a second polymeric layer 766. The silicon carbide (SiC) interposer 16 is interposed between the glass layer 762 and the first polymeric layer 766. The glass layer 762 is interposed between the silicon carbide (SiC) interposer 16 and the second polymeric layer 766 for defining a hybrid dielectric layer 822.

As shown in FIGS. 23 and 24, the second outer surface 22 of the silicon carbide (SiC) interposer 16 abuts the first outer surface 714 of the dielectric layer 712. A second silicon carbide (SiC) interposer 800 has a first outer surface 802 and a second outer surface 804. A second plurality of interposer connectors 806 are formed in situ within the second silicon carbide (SiC) interposer 800. The first outer surface 802 of the second silicon carbide (SiC) interposer 800 abuts the second outer surface 716 of the dielectric layer 712. A second interface 738 is between the first outer surface 802 of the second silicon carbide (SiC) interposer 800 and the second outer surface 716 of the dielectric layer 712 for electrically connecting the second plurality of interposer connectors 806 to the plurality of electrical connectors 718. The dielectric layer 712 is interposed between the silicon carbide (SiC) interposer 16 and the second silicon carbide (SiC) interposer 800 for defining a dielectric core 810.

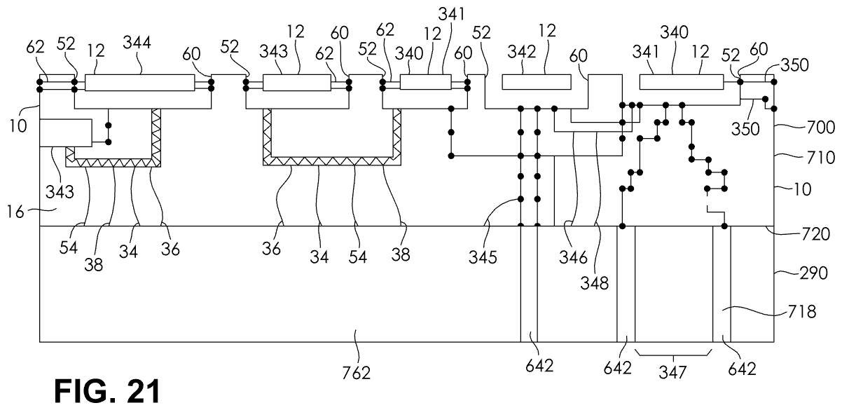

FIG. 21 illustrates a recess 60 formed in the first outer surface 20 of the silicon carbide (SiC) interposer 16. The integrated circuit die 112 is disposed in the recess 60 and is thermally coupled to the silicon carbide (SiC) interposer 16 for providing a heat sink 62 for the integrated circuit die 112.

At least one of the plurality of connectors 30 may be formed in situ within the silicon carbide (SiC) interposer 16 at an angle 40 relative to the first outer surface 20 or an angular monolithic 42 via formed at an angle relative to the first outer surface 20. The silicon carbide (SiC) interposer 16 may be selected from the group consisting of silicon carbide (SiC), gallium nitride (GaN) aluminum nitride (AlN), synthetic diamond, glass and their respective compounds and alloyed variants engineered to enhance the quantum conversion process.

FIGS. 15-39A illustrate the method of making the system level semiconductor IC-substrate, interconnect fabric and integrated electronic systems 700. The method for creating an improved semiconductor IC substrate for supporting and interconnecting integrated circuit die or multiple dies comprises the steps of depositing a silicon carbide (SiC) layer on a dielectric layer. A laser irradiates the silicon carbide (SiC) to form carbon electrical connectors. An interconnection is created in the dielectric layer by semi additive and/or, damascene and/or dual damascene pattering to create a fan out and chip to chip interconnection.

An alternative method includes the steps of depositing a silicon carbide (SiC) layer on a dielectric layer. A laser irradiates the silicon carbide (SiC) to form carbon electrical connectors. An interconnection is created in the dielectric layer by semi additive and/or, damascene and/or dual damascene pattering to form electrical connectors. An interconnection is created between the carbon electrical connectors and the electrical connectors to form electrical conduits for integrated circuit die.

FIGS. 17 and 27 illustrate an alternative method comprising the steps of depositing a silicon carbide (SiC) layer on a first dielectric layer. A laser irradiates the silicon carbide (SiC) to form carbon electrical connectors. Silicon carbide (SiC) layer is deposited on a second dielectric layer. An interconnection is created in the first and second dielectric layer by semi additive and/or, damascene and/or dual damascene pattering to form electrical connectors. An interconnection is created between the carbon electrical connectors and the electrical connectors to form electrical conduits for integrated circuit die.

FIG. 18 illustrates an alternative method comprising the steps of depositing a first silicon carbide (SiC) layer on a dielectric layer. A second silicon carbide (SiC) layer is deposited on the dielectric layer. A laser irradiates the first and second silicon carbide (SiC) to form carbon electrical connectors. An interconnection is created in the dielectric layer by semi additive and/or, damascene and/or dual damascene pattering to form electrical connectors. An interconnection is created between the carbon electrical connectors and the electrical connectors to form electrical conduits for integrated circuit die.

FIGS. 25 and 26 illustrate an alternative method comprising the steps of depositing a silicon carbide (SiC) layer on a first dielectric layer. A second dielectric layer is deposited on the first dielectric layer. A laser irradiates the silicon carbide (SiC) to form carbon electrical connectors. An interconnection is created in the first and second dielectric layer by semi additive and/or, damascene and/or dual damascene pattering to form electrical connectors. An interconnection is created between the carbon electrical connectors and the electrical connectors to form electrical conduits for integrated circuit die.

FIG. 28 illustrates an alternative method comprising the steps of depositing a silicon carbide (SiC) layer on a first dielectric layer. A laser irradiates the silicon carbide (SiC) to form carbon electrical connectors. A second dielectric layer is deposited on the silicon carbide (SiC) layer. A third dielectric layer is deposited on the second dielectric layer. An interconnection is created in the first, second and third dielectric layer by semi additive and/or, damascene and/or dual damascene pattering to form electrical connectors. An interconnection is created between the carbon electrical connectors and the electrical connectors to form electrical conduits for integrated circuit die.

FIGS. 23 and 24 illustrate an alternative method comprising the steps of depositing a first silicon carbide (SiC) layer on a dielectric layer. A second silicon carbide (SiC) layer is deposited on the dielectric layer. A laser irradiates the first and second silicon carbide (SiC) to form carbon electrical connectors. An interconnection is created in the dielectric layer by semi additive and/or, damascene and/or dual damascene pattering to form electrical connectors. An interconnection is created between the carbon electrical connectors and the electrical connectors to form electrical conduits for integrated circuit die.

The proposed architecture and fabrication method of making details the formation of system level semiconductor IC substrate. The system level semiconductor IC-substrate features the following attributes:
Both single sided and double sides substrate
The single sided variants showing a set of redistribution and interconnect layers at one side of the QCIA substrate layer containing the QCIA structure with the vertical interconnect omni directional vias
The Double-sided variant shows at least two sets of redistribution and interconnect layers at both sides of the QCIA substrate layer containing the QCIA structure with the vertical interconnect omni directional vias.
The system level variants showing a combined single and double sided QCIA substrates and featuring, double sided assembly and at least two sets of QCIA interconnect layers at two opposite sides.
The system level substrate illustrated here is an example. Additional stacking tiers of QCIA substrates are manufacturable by sequential stacking of alternating QCIA interconnect layers and redistribution layers as required by the specified system design.
The proposed invention having multiple variants and posses a wide array of scalable design rule capabilities. A set of design rules and their progressive scaling capabilities are listed in Table below.
The corresponding architectural variants representing one plausible spectrum of design rule scalability roadmap are shown in Figures
The concept invented in this application offers the following attributes
The ability to fabricate a system on substrate and/or interconnect fabric interposers at large size that is constrained by the wafer reticle size limitation
The ability to fabricate a system on substrate and/or interconnect fabric interposer with material set that has superior thermal and power delivery characteristics. This uses SiC, graphene, converted SiC.

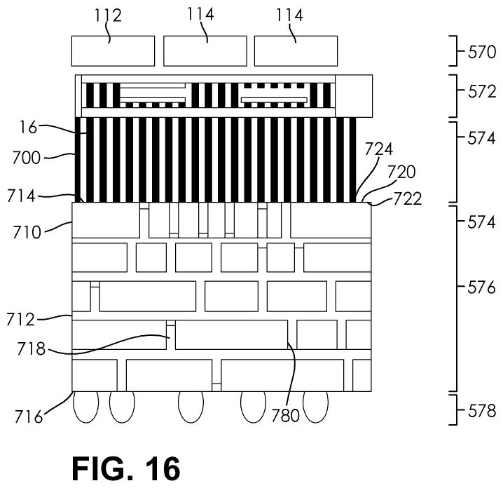

FIG. 15 illustrates the process of creating an interconnect fabric architecture using laser conversion patterning QCIA technology in combination with semi additive and/or, damascene and/or, dual damascene pattering to create a fan out and chip to chip interconnection at multiple levels (QCIA with Redistribution and interconnect layers)-QCIA with polymer RDL (FIGS. 16-18). Where the RDLs can be fabricated on one side of the QCIA core FIG. 16, on both sides of the core FIG. 17, and with chiplet assembled on either one side (FIGS. 16 & 17) or both sides of the core FIG. 18.

FIG. 15 further illustrates a FIGS. 15-18 illustrates a new interposer 10 utilizing quantum conversion pattering (QCP) wherein no drilling, no etching, no Cu sputtering, no plating or metal deposition is required. The interposer 10 may include omni directional geometry and variable depth interconnect. FIG. 15 specifically illustrates an omni-directional monolithic vias 702 and simple 3D direct write process suitable for 3D packaging and heterogenous integration. The conversion patterning includes laser+SiC resulting in Si+Graphene+SiC.

FIG. 16 further illustrates a single sided QCIA substrate having a fan out capabilities built on thin QCIA SiC with grapheme vias. Chiplets are interconnected directly on the SiC QCIA. Redistribution (RDL) Layers are built equentially on the other side of the QCIA core to fan out. The bottom side of the substrate is assembled to an interposer or HDI substrate.

FIG. 17 further illustrates a double sided QCIA substrate having a double sided RDL built on thick QCIA SiC core with graphene vias. Chiplets are interconnected on the RDL at the front side of the SiC QCIA. The bottom side of the substrate is connected directly to a board or PCB.

FIG. 18 further illustrates a system level panel substrate (SLPS) built on QCIA having a system level panel substrate that is the ultimate simplication target for the substrate. The QCIA process is used to fabricate a full panel with two sides QCIA delineating a high RDL layer count. The configuration features multiple embedded components and different levels of embedded chips in addition to the double-sided assembly of chiplets and components. The double sided assembly is made possible by two QCIA layers molded at each side of the panel.

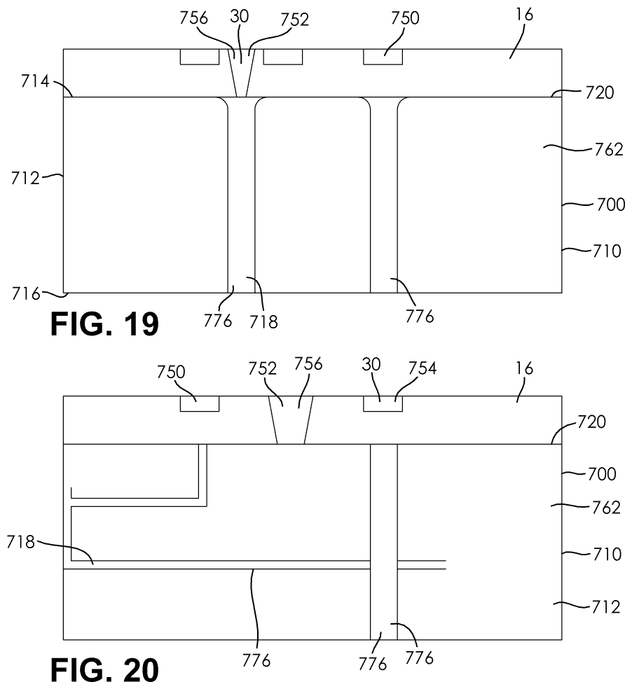

FIG. 19 illustrates the process of creating a Hybrid layer interconnect fabric and integrated circuit substrate using SiC deposited on glass. Followed by the conversion of SiC layer into conductive graphene to form the inplane interconnect circuitry. The in plane interconnect circuitry made of converted SiC to graphene are connected per the specific device design with the vertical interconnect structure connecting the different layers. The vertical interconnect structure inside the SIC can be mad either of converted graphene or traditional Cu deposits. The glass layer contains through glass vias (TGVs) for vertical interconnect-QCIA on glass.

FIG. 20 illustrates the process of creating a Hybrid layer interconnect fabric and integrated circuit substrate using SiC deposited on glass. Followed by the conversion of SiC layer into conductive graphene to form the in plane interconnect circuitry. The in plane interconnect circuitry made of converted SiC to graphene are connected per the specific device design with the vertical interconnect structure connecting the different layers. The vertical interconnect structure inside the SIC can be mad either of converted graphene or traditional Cu deposits. The glass layer contains through glass vias (TGVs) for vertical interconnect-QCIA on glass. The glass layer in this invention may also be made to contain optical waveguides to allow for a both hybrid optical and electronic interconnect structure formation. (QCIA OPTIKS on glass).

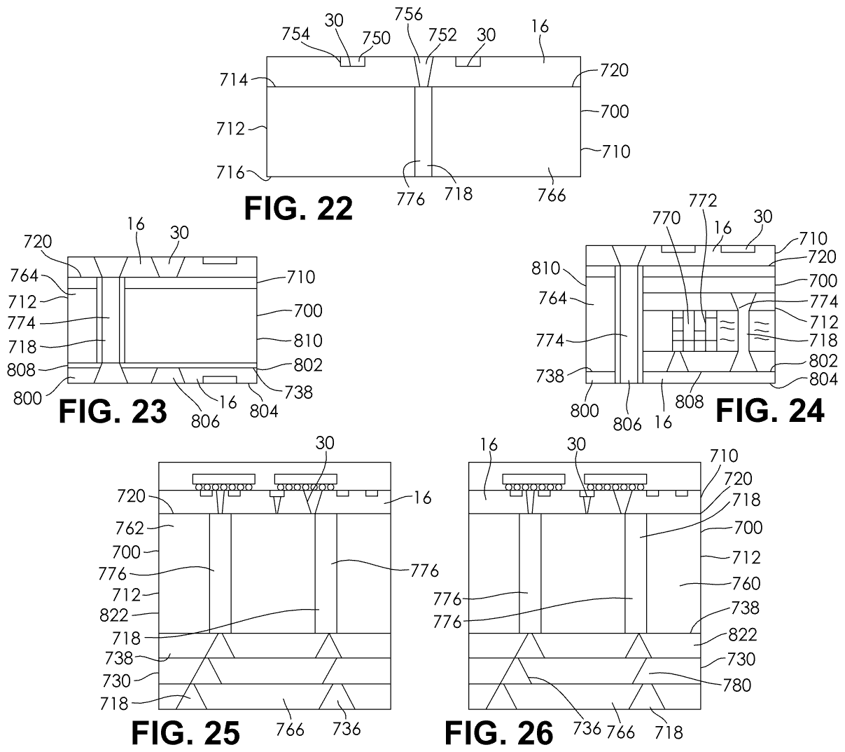

FIG. 22 illustrates the process of creating a Hybrid layer interconnect fabric and integrated circuit substrate using SiC deposited on Silicon. Followed by the conversion of SiC layer into conductive graphene to form the in plane interconnect circuitry. The in-plane interconnect circuitry made of converted SiC to graphene are connected per the specific device design with the vertical interconnect structure connecting the different layers. The vertical interconnect structure inside the SiC can be made either of converted graphene or traditional Cu deposits. The Silicon layer contains through Silicon vias (TSVs) for vertical interconnect-QCIA on Silicon.

FIGS. 23 and 24 illustrate the process of creating a Hybrid layers interconnect fabric and integrated circuit substrate using SiC deposited on organic composite material(s). Followed by the conversion of SiC layer into conductive graphene to form the in plane interconnect circuitry. The in-plane interconnect circuitry made of converted SiC to graphene are connected per the specific device design with the vertical interconnect structure connecting the different layers. The vertical interconnect structure inside the SiC can be made either of converted graphene or traditional Cu deposits. The Silicon layer contains through Silicon vias (TSVs) for vertical interconnect-Hyperion QCIA on Organic reinforced composite materials. SiC is deposited on an organic composite material then converted to formulate QCIA. FIG. 23 illustrates the deposition of SiC layer on top of organic composite core material with two configuration. FIG. 23 further illustrate a monolithic composite core material with plated through hole.

FIG. 24 illustrates a multilayer core material allowing for active, passive and inductor component embedding. The embedded devices in this configuration are electrically connected to the deposited SiC which in turn will be converted to QCIA forming a connection between the embedded devices and the Chiplets to be assembled on the top/bottom of the core in subsequent assembly steps.

FIG. 25 illustrates the process to build a fully integrated system on substrate panel using QCIA and its hybrid layer structures. The system includes a core layer of Glass with TGV, a deposited SiC layer, the deposited SiC layer is converted to QCIA circuit using the laser conversion process. Polymeric Redistribution layers are formed on one or both sides of the SiC converted layer as shown in FIG. 25. FIG. 26 illustrates another variant wherein the glass can be replaced by Silicon and the GV process is replaced with the TSV process.

FIG. 27 illustrates the process to build a fully integrated optoelectronics system on substrate panel using QCIA and its hybrid layer structures containing both converted SiC interconnects as well as optical interconnects through waveguides fabricated in-situ within the glass, the SiC and/or both. The system is referred to as Hyperion QCIA-Optiks. The system includes a core layer of Glass with TGV, a deposited SiC layer, the deposited SiC layer is converted to QCIA circuit using the laser conversion process. Polymeric Redistribution layers are formed on one or both sides of the SiC converted layer as shown in FIG. 25.

FIG. 25 illustrates the process to build a fully integrated system on 2.5D interposer panel using QCIA and its hybrid layer structures on Glass. The system includes a core layer of Glass with TGV, a deposited SiC layer, the deposited SiC layer is converted to QCIA circuit using the laser conversion process. Polymeric Redistribution layers are formed on one or both sides of the SiC converted layer as shown in FIG. 6 In another variant the glass can be replaced by Silicon (FIG. 26). The 2.5 interposer contain an integrated localized interconnect (ILI) structure embedded into the RDL layers to form a 2.5 interconnection structure among the chiplets to be assembled on the top side of the SiC/Glass interposer (FIG. 28). The integrated localized interconnect (ILI) structure can be fabricated with multiple semiconducting materials and/or dielectric options; these includes—but not limited to—Silicon, Silicon carbide, organic dielectrics. The silicon material for the ILI structure can be fabricated using damascene process, dual damascene process or semi additive patterning process. Similarly, the SiC material for the ILI structure can be fabricated using damascene process, dual damascene process or semi additive patterning process. Additionally, the SiC material for the ILI structure can also be selectively converted to Graphene and uses QCP (Quantum conversion patterning) process to form the integrated circuitry structure as required.

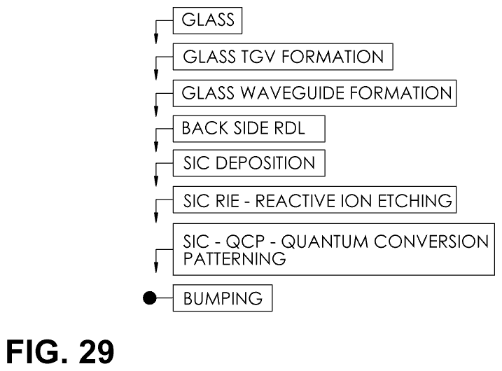

FIG. 29 illustrates the process flow to build an integrated system on 2.5D interposer panel using QCIA and its hybrid layer structures on Glass. The system includes a core layer of Glass with TGV, a deposited SiC layer, the deposited SiC layer is converted to QCIA circuit using the laser conversion process. Polymeric Redistribution layers are formed on one or both sides of the SiC converted layer. The 2.5 interposer contain an integrated localized interconnect (ILI) structure embedded into the RDL layers to form a 2.5 interconnection structure among the chiplets to be assembled on the top side of the Si/SiC interposer

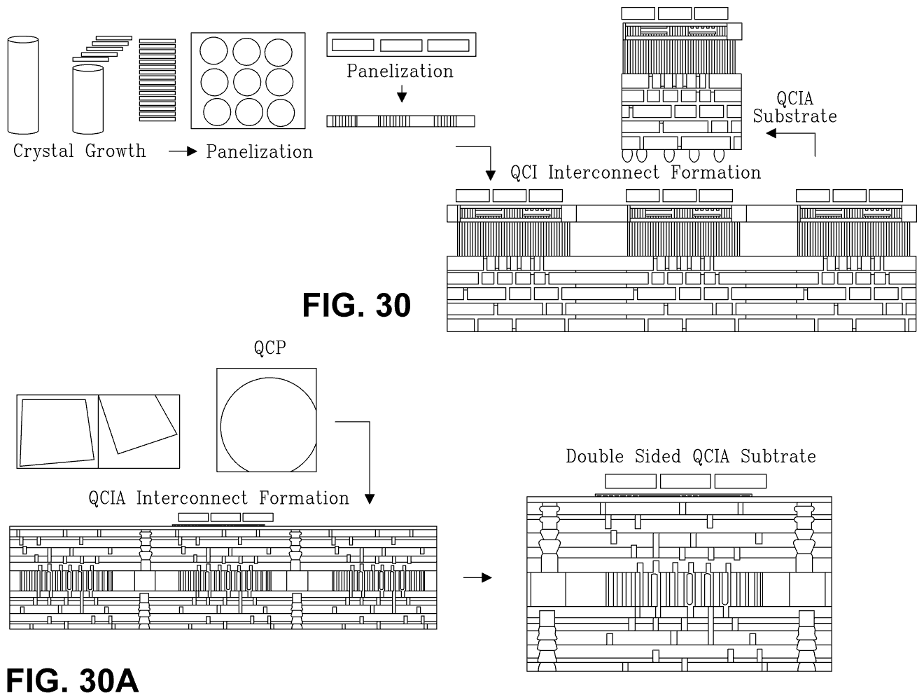

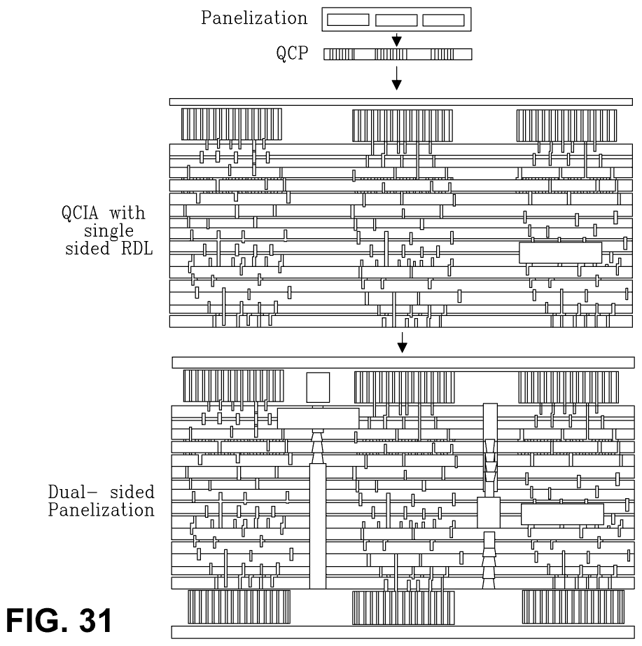

FIGS. 30, 30A and 31 respectively illustrates the process flow to build a single sided, double sided and system level panel substrate using the QCP patterning process and the QCIA redistribution layer process. The system includes a core layer of either a converted SiC (QCIA), a Glass core with TGV or a Silicon core with TSV. In this system, a deposited SiC layer is placed directly on top and below the core layer, the deposited SiC layer is converted to QCIA circuit using the laser conversion process. Polymeric Redistribution layers are formed on one or both sides of the SiC converted layer. The 2.5 interposer contain an integrated localized interconnect (ILI) structure embedded into the RDL layers to form a 2.5 interconnection structure among the chiplets to be assembled on the top side of the Si/SiC interposer. Chiplets are either assembled on one or both sides of the core structure using a two sided carrier process to bump the outermost layer of the redistribution layers.

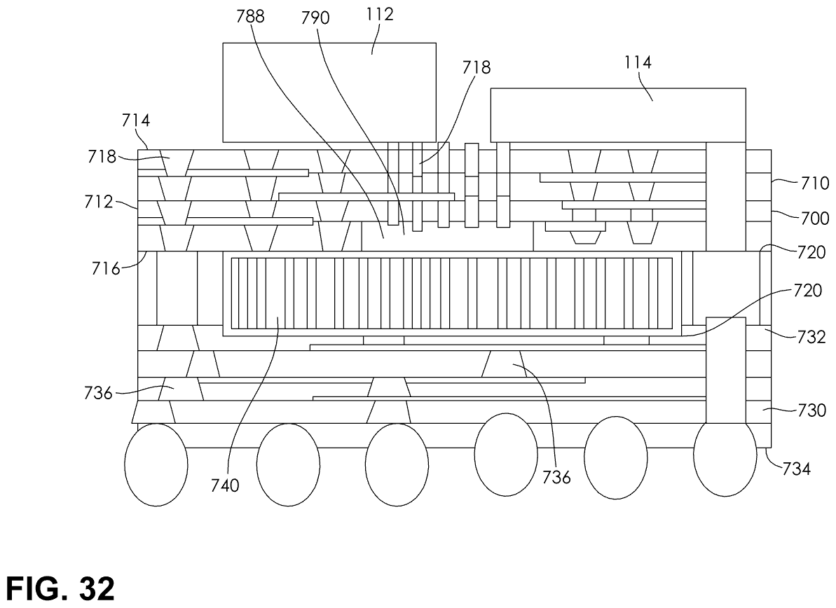

FIG. 32 illustrates the architecture of a double sided QCIA substrate featuring redistribution layers located on both sides of the QCIA core and fabricated using Ajinomoto build up film material with semi-additive process (Hyperion QCIA Gen 1). Similarly, the architecture of a double sided QCIA substrate featuring redistribution layers located on both sides of the QCIA core and fabricated using photosensitive build up film material (Hyperion QCIA Gen 1.5).

FIG. 32 illustrates the architecture of a double sided QCIA substrate featuring redistribution layers located on both sides of the QCIA core and fabricated using photosensitive build up film material and dual damascene process (QCIA Gen 3). The double sided QCIA substrate may include embedded bridges <0.5 um L/S and <1 um via) and/or embedded thermal CHIPS. The SiC QCIA core may include grapheme Via: 10-100 um diameter, Via pitch 20-150 um and core layer metallization and RDL including L/S 2/2-1/1 um Via size 5-3 um. FIG. 32 further illustrates a dielectric based RDL, L/S 0.4/0.4 um, damascene based process with low K dielectric, Cu-deposition, high K capacitors, dual damascene pattering with via-first approach, planarization and in-situ capacitor fabrication, dual damascene process is built with QCIA substrate. The Gen-3 QCIA core construct features and inorganic mold material encapsulating the QCIA SiC wafers for subsequent dry process step capability and damascene process CMP steps. QCIA Thermo conductivity and superior thermal physical properties offer the opportunity for the back side RDL to remain consistent with Gen-1 and/or Gen-1.5. The SiC QCIA core may include grapheme Via: 10-100 um diameter, Via pitch 20-150 um and core layer metallization.

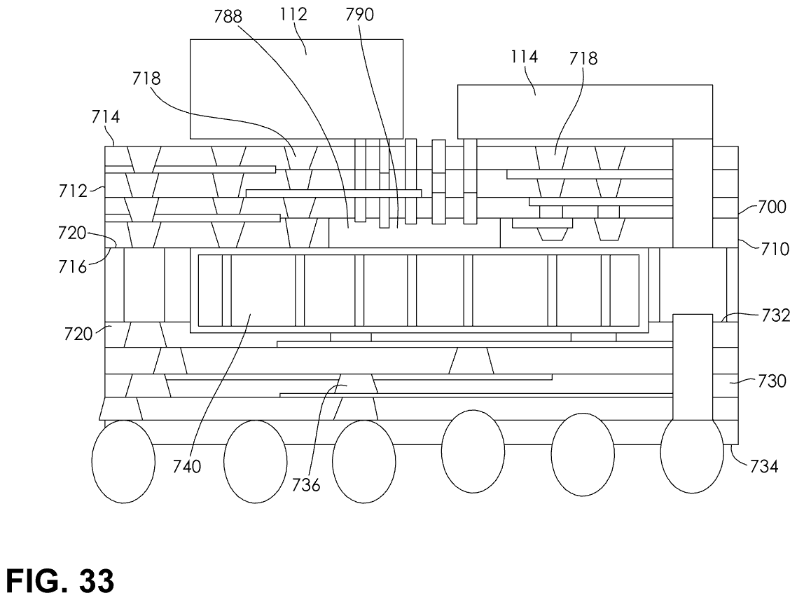

FIG. 33 illustrates a double sided QCIA substrate may include embedded bridges <0.5 um L/S and <1 um via) and/or embedded thermal CHIPS. The SiC QCIA core may include grapheme Via: 100 um diameter, Via pitch 150+um and core layer metallization and RDL including US 2/2-1/1 um Via size 5-3 um.

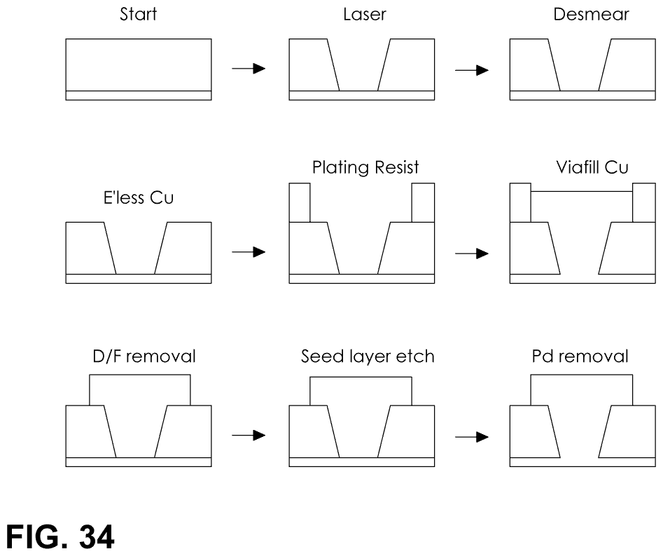

FIG. 34 illustrates a semi-additive process flow for the buildup with combined wet and dry processes utilizing: (1) ABF+laser drilling for course design rules and (2) PID+Litho defined vias for fine features. Both available with QCIA substrate.

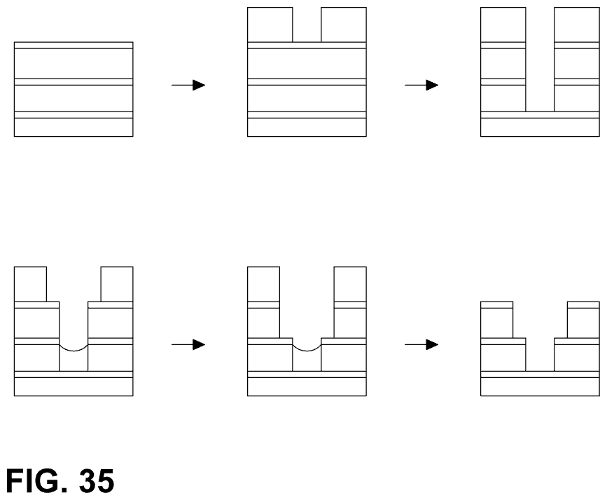

FIG. 35 illustrates a process for a Via first approach.

FIG. 18 illustrates the architecture of a double sided QCIA substrate featuring redistribution layers located on both sides of the QCIA core and fabricated using either photosensitive build up film material or Ajinomoto Build up film material followed by double sided bumping to create a double sided assembly for chiplets (QCIA Gen 2). FIG. 18 further illustrates system level substrate panel substrate (SLSP-QCIA) including extending the substrate size to a full panel size (510 mm×515 mm), PID based RDL L/S 1/1 um, all dry processes for BU RDL, dual QCIA with graphene metallization on both sides, multilevel embedded bridges and IPD throughout the construction, featuring panel level SMT and assembly.

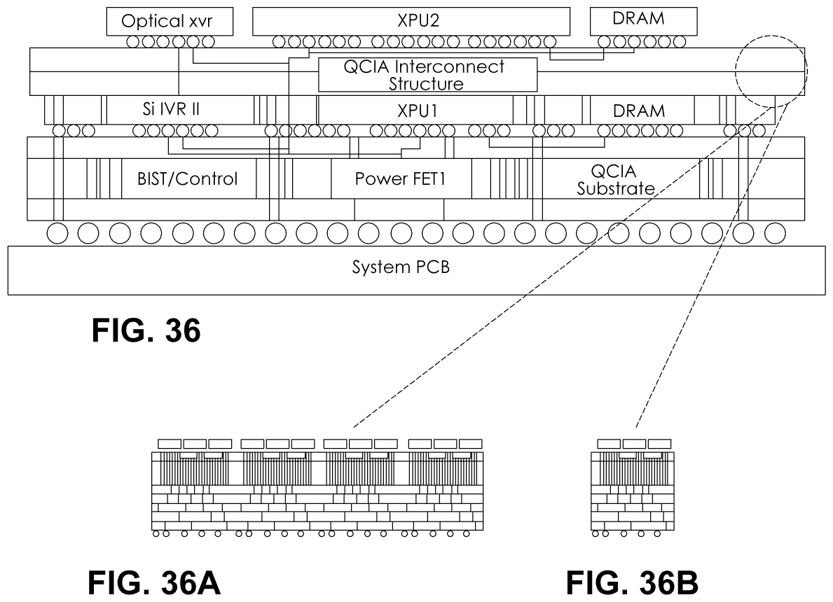

FIGS. 36, 36A and 36B illustrate the architecture of a 3D fully integrated electronic and/or optoelectronic system on substrate panel using QCIA and its hybrid layer structures. The system includes an integrated, localized, interconnect embedded structure. The integrated localized interconnect structure ILI is made of Si chip, Si Chip with TSV, sic chip, SiC chip with QCIA circuit and QCIA vertical interconnect structure. The process allows for the dimensions of the interconnect structure to exceed the limitation of the full reticle size as defined by the width and length of the substrate system unit exceeding 3-5 times that of the reticle size and approaching the dimensions of 100×100 mm all the way to 510×515 mm. The Hyperion 3D integrated circuit system features multi tiered QCIA layers enabling vertical interconnection, horizontal interconnections and backside power delivery and thermal management interconnections. The backside power delivery feature of the architecture uses Hyperion QCIA converted Si Metallization to provide power into the backside of the chiplets assembled at the bottom of the QCIA layer using converted SiC into graphene as the power delivery routes referred to as QCIA power interconnect (QCIA-PI)

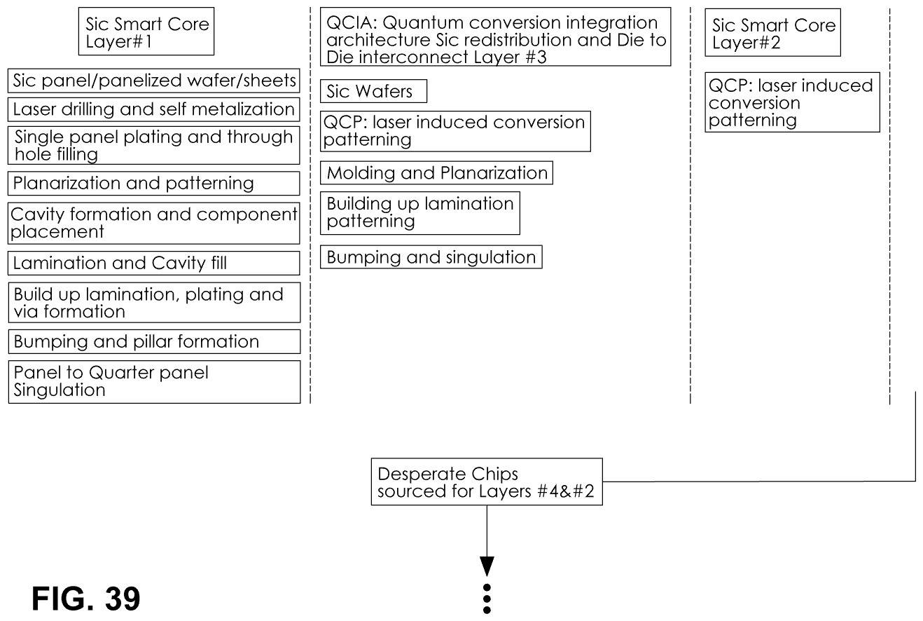

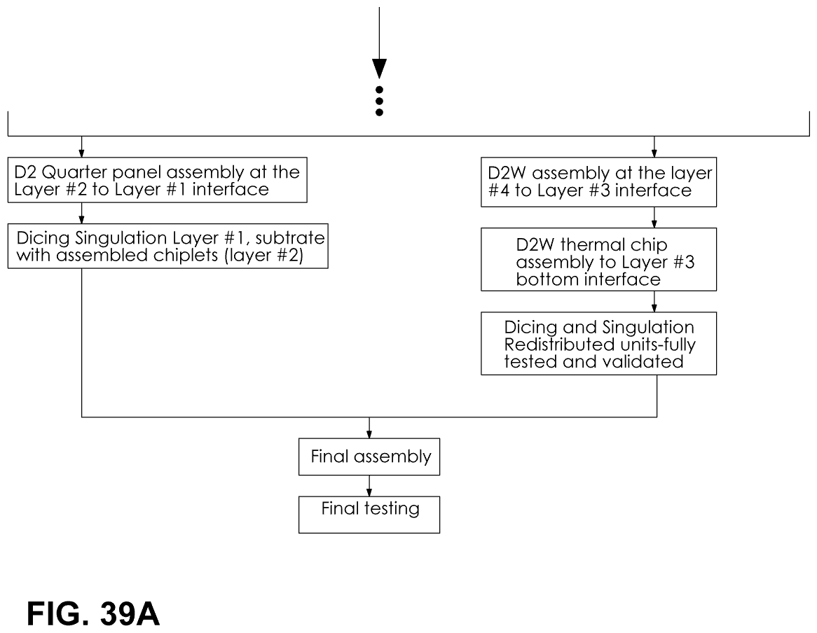

FIGS. 39 and 39A illustrate the process flow steps for creating a 3D fully integrated electronic and/or optoelectronic system on substrate panel using QCIA and its hybrid layer structures.

While the foregoing is directed to embodiments of the present disclosure, other and further embodiments of the disclosure may be devised without departing from the basic scope thereof, and the scope thereof is determined by the claims that follow.

Comparison between the proposed invention and the state of the art

| State of the Art | Proposed Invention |
|---|---|
| Build up substrate | 3D monolithic substrate |
| packaging process | packaging process |
| Semi additive patterning process | Quantum conversion |
| Subtractive patterning process | patterning process |
| Damascene and double | |
| damascene patterning | |
| process | |
| Additive Manufacturing | 3D in-situ Manufacturing |
| | 3D in-situ interconnect manufacturing |
| | In-situ 3D interconnect fabrication |
| Stacked via interconnect | Angular monolithic via |
| Cu metallization | C3-interconnect |
| conductor lines | Conductive carbon connections |
| | Converted-Carbon Connection |

The subject invention may be described by a complex 2X3X5 matrix:

| | | | Connection Type | | |
|---|---|---|---|---|---|
| | | | Created by | | |
| | | | quantum conversion | | |
| | Device Type | | patterning approach | | |
| Integration scheme | Interposer | Package | Electric | Optical | Hybrid |
| 2D | X | X | X | X | X |
| 2.5D | — | X | X | X | X |
| 3D | X | — | X | X | X |
| 3D w/interleaved SiC | X | X | X | X | X |
| Combined 2D, | X | — | X | X | X |
| 2.5D and 3D | | | | | |
| (SiCcube interconnect | | | | | |
| depicted in FIG. 6d) | | | | | |

What is claimed is:

1. An improved semiconductor IC substrate for supporting and interconnecting integrated circuit die or multiple dies, comprising:
a silicon carbide (SiC) interposer having a first outer surface and a second outer surface;
a plurality of interposer connectors formed in situ within said silicon carbide (SiC) interposer;
a dielectric layer having a first outer surface and a second outer surface;
a plurality of electrical connectors formed within said dielectric layer; and
an interface between said second outer surface of said silicon carbide (SiC) interposer and said first outer surface of said dielectric layer for electrically connecting said plurality of interposer connectors to said plurality of electrical connectors.

2. The improved semiconductor IC substrate as set forth in claim 1, wherein said plurality of interposer connectors are carbon electrical connectors formed by laser irradiation of said silicon carbide (SiC) to form said carbon electrical connectors.

3. The improved semiconductor IC substrate as set forth in claim 1, wherein said plurality of interposer connectors are carbon portions, carbon vias, graphene portions, graphene vias or optical wave guide connectors formed by a tunnel in said silicon carbide (SiC) by carbon rich tunnel walls.

4. The improved semiconductor IC substrate as set forth in claim 1, wherein said dielectric layer is silicon, glass, organic composite material, or polymeric material.

5. The improved semiconductor IC substrate as set forth in claim 1, wherein said plurality of electrical connectors are passive electrical components, active electrical components, electrical conductive portions, electrical conductive vias, electrical conductive plated though holes, redistribution conductive channels, input coupler, output coupler, integrated localized interconnect structure, embedded bridges, embedded thermal CHIPS or optical wave guide connector formed by a tunnel in said dielectric layer.

6. The improved semiconductor IC substrate as set forth in claim 1, wherein said interface is direct abutment or adhesive.

7. The improved semiconductor IC substrate as set forth in claim 1, wherein said second outer surface of said silicon carbide (SiC) interposer abuts said first outer surface of said dielectric layer;
a second dielectric layer having a first outer surface and a second outer surface;
a second plurality of electrical connectors formed within said second dielectric layer;
a second interface between said first outer surface of said silicon carbide (SiC) interposer and said second outer surface of said second dielectric layer for electrically connecting said plurality of interposer connectors to said second plurality of electrical connectors; and
said silicon carbide (SiC) interposer interposed between said dielectric layer and said second dielectric layer defining a silicon carbide (SiC) interposer core.

8. The improved semiconductor IC substrate as set forth in claim 1, wherein said second outer surface of said silicon carbide (SiC) interposer abuts said first outer surface of said dielectric layer;
a second silicon carbide (SiC) interposer having a first outer surface and a second outer surface;
a second plurality of interposer connectors formed in situ within said second silicon carbide (SiC) interposer;
a second interface between said first outer surface of said second silicon carbide (SiC) interposer and said second outer surface of said dielectric layer for electrically connecting said second plurality of interposer connectors to said plurality of electrical connectors; and
said dielectric layer interposed between said silicon carbide (SiC) interposer and said second silicon carbide (SiC) interposer defining a dielectric layer core.

9. The improved semiconductor IC substrate as set forth in claim 8, wherein a first integrated circuit die is electrically coupled to said first outer surface of said silicon carbide (SiC) interposer;
an second integrated circuit die is electrically coupled to said second outer surface of said second silicon carbide (SiC) interposer; and
the first integrated circuit die abutting said first silicon carbide (SiC) interposer and the second integrated circuit die abutting said second silicon carbide (SiC) interposer defining a double-sided assembly of chiplets.

10. The improved semiconductor IC substrate as set forth in claim 1, wherein said dielectric layer includes a glass layer and a polymeric layer; and
said glass layer interposed between said silicon carbide (SiC) interposer and said polymeric layer for defining a hybrid dielectric layer.

11. The improved semiconductor IC substrate as set forth in claim 1, wherein said dielectric layer includes a silicon layer and a polymeric layer; and
said silicon layer interposed between said silicon carbide (SiC) interposer and said polymeric layer for defining a hybrid dielectric layer.

12. The improved semiconductor IC substrate as set forth in claim 1, wherein said dielectric layer includes a glass layer, a first polymeric layer and a second polymeric layer; and
said silicon carbide (SiC) interposer interposed between said glass layer and said first polymeric layer, and said glass layer interposed between said silicon carbide (SiC) interposer and said second polymeric layer for defining a hybrid dielectric layer.

13. The improved semiconductor IC substrate as set forth in claim 1, wherein said second outer surface of said silicon carbide (SiC) interposer abuts said first outer surface of said dielectric layer;
a second silicon carbide (SiC) interposer having a first outer surface and a second outer surface;
a second plurality of interposer connectors formed in situ within said second silicon carbide (SiC) interposer;
said first outer surface of said second silicon carbide (SiC) interposer abuts said second outer surface of said dielectric layer;
a second interface between said first outer surface of said second silicon carbide (SiC) interposer and said second outer surface of said dielectric layer for electrically connecting said second plurality of interposer connectors to said plurality of electrical connectors; and
said dielectric layer interposed between said silicon carbide (SiC) interposer and said second silicon carbide (SiC) interposer defining a dielectric core.

14. The improved semiconductor IC substrate as set forth in claim 1, further including a recess formed in said first outer surface of said silicon carbide (SiC) interposer; and
the integrated circuit die disposed in said recess and thermally coupled to said silicon carbide (SiC) interposer for providing a heat sink for the integrated circuit die.

15. The improved semiconductor IC substrate as set forth in claim 1, wherein at least one of said plurality of connectors formed in situ within said silicon carbide (SiC) interposer is formed at an angle relative to said first outer surface or an angular monolithic via formed at an angle relative to said first outer surface.

16. The improved semiconductor IC substrate as set forth in claim 1, wherein said silicon carbide (SiC) interposer is selected from the group consisting of silicon carbide (SiC), gallium nitride (GaN) aluminum nitride (AlN), synthetic diamond, glass and their respective compounds and alloyed variants engineered to enhance the quantum conversion process.

17. A method for creating an improved semiconductor IC substrate for supporting and interconnecting integrated circuit die or multiple dies, the method comprising the steps of:
depositing a silicon carbide (SiC) layer on a dielectric layer;
laser irradiating the silicon carbide (SiC) to form carbon electrical connectors; and
creating interconnection in the dielectric layer by semi additive and/or, damascene and/or dual damascene pattering to create a fan out and chip to chip interconnection.

18. A method for creating an improved semiconductor IC substrate for supporting and interconnecting integrated circuit die or multiple dies, the method comprising the steps of:
depositing a silicon carbide (SiC) layer on a dielectric layer;
laser irradiating the silicon carbide (SiC) to form carbon electrical connectors;
creating interconnection in the dielectric layer by semi additive and/or, damascene and/or dual damascene pattering to form electrical connectors; and
creating interconnection between the carbon electrical connectors and the electrical connectors to form electrical conduits for integrated circuit die.

19. A method for creating an improved semiconductor IC substrate for supporting and interconnecting integrated circuit die or multiple dies, the method comprising the steps of:
depositing a silicon carbide (SiC) layer on a first dielectric layer;
laser irradiating the silicon carbide (SiC) to form carbon electrical connectors;
depositing the silicon carbide (SiC) layer on a second dielectric layer;
creating interconnection in the first and second dielectric layer by semi additive and/or, damascene and/or dual damascene pattering to form electrical connectors; and
creating interconnection between the carbon electrical connectors and the electrical connectors to form electrical conduits for integrated circuit die.

20. A method for creating an improved semiconductor IC substrate for supporting and interconnecting integrated circuit die or multiple dies, the method comprising the steps of:
depositing a first silicon carbide (SiC) layer on a dielectric layer;
depositing a second silicon carbide (SiC) layer on the dielectric layer;
laser irradiating the first and second silicon carbide (SiC) to form carbon electrical connectors;
creating interconnection in the dielectric layer by semi additive and/or, damascene and/or dual damascene pattering to form electrical connectors; and
creating interconnection between the carbon electrical connectors and the electrical connectors to form electrical conduits for integrated circuit die.

21. A method for creating an improved semiconductor IC substrate for supporting and interconnecting integrated circuit die or multiple dies, the method comprising the steps of:
depositing a silicon carbide (SiC) layer on a first dielectric layer;
depositing a second dielectric layer on the first dielectric layer;
laser irradiating the silicon carbide (SiC) to form carbon electrical connectors;
creating interconnection in the first and second dielectric layer by semi additive and/or, damascene and/or dual damascene pattering to form electrical connectors; and
creating interconnection between the carbon electrical connectors and the electrical connectors to form electrical conduits for integrated circuit die.

22. A method for creating an improved semiconductor IC substrate for supporting and interconnecting integrated circuit die or multiple dies, the method comprising the steps of:
depositing a silicon carbide (SiC) layer on a first dielectric layer;
laser irradiating the silicon carbide (SiC) to form carbon electrical connectors;
depositing a second dielectric layer on the silicon carbide (SiC) layer;
depositing a third dielectric layer on the second dielectric layer;
creating interconnection in the first, second and third dielectric layer by semi additive and/or, damascene and/or dual damascene pattering to form electrical connectors; and
creating interconnection between the carbon electrical connectors and the electrical connectors to form electrical conduits for integrated circuit die.

23. A method for creating an improved semiconductor IC substrate for supporting and interconnecting integrated circuit die or multiple dies, the method comprising the steps of:
depositing a first silicon carbide (SiC) layer on a dielectric layer;
depositing a second silicon carbide (SiC) layer on the dielectric layer;
laser irradiating the first and second silicon carbide (SiC) to form carbon electrical connectors;
creating interconnection in the dielectric layer by semi additive and/or, damascene and/or dual damascene pattering to form electrical connectors; and
creating interconnection between the carbon electrical connectors and the electrical connectors to form electrical conduits for integrated circuit die.
